(19) United States
(12) Patent Application Publication
(10) Pub. No.: US 2024/0222553 A1
(43) Pub. Date: Jul. 4, 2024

(54) DISPLAY DEVICE

(71) Applicant: Samsung Display Co., LTD., Yongin-si (KR)

(72) Inventors: Gun Woo KO, Yongin-si (KR); Changwook KIM, Yongin-si (KR); Jung-Hyun CHO, Yongin-si (KR); Heung Shik PARK, Seoul (KR)

(73) Assignee: Samsung Display Co., LTD., Yongin-si (KR)

(21) Appl. No.: 18/515,263

(22) Filed: Nov. 21, 2023

(30) Foreign Application Priority Data
Jan. 2, 2023 (KR) 10-2023-0000349

(51) Int. Cl. H01L 33/20; G06F 3/044; H01L 25/075; H01L 33/52

(52) U.S. Cl. CPC H01L 33/20; G06F 3/0446; H01L 25/0753; H01L 33/52

(57) ABSTRACT

A display device includes pixel electrodes, a pixel defining film and including pixel openings, an encapsulation layer on the pixel electrodes and the pixel defining film, a sensing electrode on the encapsulation layer, a first insulating layer on the sensing electrode and including openings respectively overlapping the pixel openings, and a second insulating layer on the first insulating layer and having a higher refractive index than the first insulating layer, and each of the openings of the first insulating layer includes a main portion including a side and a chamfer portion and an extension protruding from the main portion, and a value obtained by subtracting a width of the extension from a length of a side of the main portion is 2A, and a length of the chamfer portion is B, has a value of 2A/B in a range of about 1 to about 15.

### CROSS-REFERENCE TO RELATED APPLICATION(S)

This application claims priority to and benefits of Korean Patent Application No. 10-2023-0000349 under 35 U.S.C. § 119 filed in the Korean Intellectual Property Office on Jan. 2, 2023, the entire contents of which are incorporated herein by reference.

### BACKGROUND

### 1. Technical Field

Embodiments disclosure relate to a display device, and, to a display device having improved transmittance and a small difference in display quality according to an azimuth angle, and an electronic device including the same.

### 2. Description of the Related Art

A display device is a device for displaying an image, and may include a liquid crystal display (LCD), an organic light emitting diode (OLED) display, and the like. The display device is used in various electronic devices such as a mobile phone, a navigation device, a digital camera, an electronic book, a portable game machine, and various terminals.

A display device such as an organic light emitting display device may have a structure that can be bent or folded by using a flexible substrate.

In a small electronic device such as a mobile phone, an optical element such as a camera sensor and an optical sensor is formed in a bezel area around a display area, but as a size of the display area is increased while a size of a peripheral area of the display area is gradually decreased, a technology in which a camera or an optical sensor may be disposed on a rear surface of the display area is being developed.

The above information disclosed in this background section is only for enhancement of understanding of the background of the disclosure, and therefore it may contain information that does not form the prior art that may already be known to a person of ordinary skill in the art.

### SUMMARY

Embodiments provide a display device that may improve light emitting efficiency and display quality.

Embodiments provide a display device in which front display luminance is improved and a difference in display quality according to an azimuth angle is small.

The technical objectives to be achieved by the disclosure are not limited to those described herein, and other technical objectives that are not mentioned herein would be clearly understood by a person skilled in the art from the description of the disclosure.

An embodiment provides a display device that may include pixel electrodes disposed on a substrate; a pixel defining film disposed on the pixel electrodes and including pixel openings respectively overlapping the pixel electrodes; an encapsulation layer disposed on the pixel electrodes and the pixel defining film; a sensing electrode disposed on the encapsulation layer; a first insulating layer disposed on the sensing electrode and including openings respectively overlapping the pixel openings; and a second insulating layer disposed on the first insulating layer and has a higher refractive index than a refractive index of the first insulating layer, wherein each of the openings of the first insulating layer may include a main portion including a side and a chamfer portion and an extension protruding from the main portion, and in case that a value obtained by subtracting a width of the extension from a length of a side of the main portion is 2A, and a length of the chamfer portion is B, a value of 2A/B is in a range of about 1 to about 15.

The width of the extension may be in a range of about 1 μm to about 12 μm.

The length of the chamfer portion may be in a range of about 2 μm to about 10 μm.

A planar shape of the main portion including the chamfer portion may be a substantially octagonal shape, and include four extensions.

The extensions may be disposed in a substantially x shape.

The extension may be disposed at a center of the side of the main portion of the first insulating layer.

The first insulating layer may include additional openings, and each of the additional openings may include extensions disposed in a substantially + shape.

A planar shape of the main portion including the chamfer portion may be a substantially regular octagonal shape.

Each of the openings of the first insulating layer may include two extensions, four extensions, or eight extensions.

Two of the extensions may form an angle of about 45 degrees, about 90 degrees, about 135 degrees, or about 180 degrees.

An embodiment provides a display device that may include pixel electrodes disposed on a substrate; a pixel defining film disposed on the pixel electrodes and including pixel openings respectively overlapping the pixel electrodes; an encapsulation layer disposed on the pixel electrodes and the pixel defining film; a sensing electrode disposed on the encapsulation layer; a first insulating layer; disposed on the sensing electrode and including openings respectively overlapping the pixel openings; and a second insulating layer disposed on the first insulating layer and having a higher refractive index than a refractive index of the first insulating layer, wherein each of the openings of the first insulating layer may include a main portion and extensions protruding from the main portion, and the main portion may include a protrusion at each corner of the main portion.

Each of the openings of the first insulating layer may include two extensions, four extensions, or eight extensions.

Two of the extensions may form an angle of about 45 degrees, about 90 degrees, about 135 degrees, or about 180 degrees.

A width of the protrusion may be greater than a width of an extension of the extensions.

At least one of the extensions may protrude from the protrusion of the main portion.

A step may be formed at a portion in which the extension protruding from the protrusion and the protrusion contact each other.

At least one of the extensions may not contact the protrusion of the main portion.

An embodiment provides a display device that may include pixel electrodes disposed on a substrate; a pixel defining film disposed on the pixel electrodes and including pixel openings respectively overlapping the pixel electrodes; an encapsulation layer disposed on the pixel electrodes and the pixel defining film; a sensing electrode disposed on the encapsulation layer; a first insulating layer disposed on the sensing electrode and including openings respectively overlapping the pixel openings; and a second insulating layer disposed on the first insulating layer and having a higher refractive index than a refractive index of the first insulating layer, wherein each of the openings of the first insulating layer may include a main portion and an extension protruding from the main portion, and a planar shape of the main portion has a substantially regular polygonal shape about equal to or greater than a substantially regular octagonal shape.

Each of the openings of the first insulating layer may include two extensions, four extensions, or eight extensions.

Two of the extensions may form an angle of about 45 degrees, about 90 degrees, about 135 degrees, or about 180 degrees.

According to the embodiments, light emitting efficiency of a display device may be improved by disposing an insulating layer having a difference in refractive index on a light emitting layer to transmit light to the front surface.

According to the embodiments, an opening of a first insulating layer having a low refractive index has an extension, a second insulating layer having a high refractive index is disposed in the opening and the extension, and a width and a position of the extension may be variously changed and disposed, so that a difference in display quality according to an azimuth angle does not occur or decreases, thereby providing the display quality of a certain level or more regardless of the azimuth angle.

### BRIEF DESCRIPTION OF THE DRAWINGS

The above and other aspects and features of the disclosure will become more apparent by describing in detail embodiments thereof with reference to the attached drawings, in which:

FIG. 1 illustrates a schematic perspective view of a use state of a display device according to an embodiment.

FIG. 2 illustrates an exploded schematic perspective view of a display device according to an embodiment.

FIG. 3 illustrates a block diagram of a display device according to an embodiment.

FIG. 4 illustrates a schematic top plan view of a portion of a display panel according to an embodiment.

FIG. 5 illustrates a schematic top plan view of a sensing electrode of a display panel according to an embodiment.

FIG. 6 illustrates a schematic cross-sectional view of a portion of a display area in a display device according to an embodiment.

FIG. 7 illustrates a schematic top plan view of a portion of a display device according to an embodiment.

FIG. 8 illustrates a schematic cross-sectional view of a step of a manufacturing process of a display device according to an embodiment.

FIGS. 9A to FIG. 17 illustrate features of the embodiment of FIG. 7.

FIG. 18 to FIG. 25 illustrate various modifications of the embodiment of FIG. 7.

FIGS. 26A and 26B each illustrate a main portion of a first insulating layer according to an embodiment.

FIG. 27 to FIG. 32 illustrate openings of a first insulating layer according to various embodiments.

FIG. 33 illustrates a main portion of a first insulating layer according to an embodiment.

FIG. 34 illustrates an opening of a first insulating layer according to an embodiment.

### DETAILED DESCRIPTION OF THE EMBODIMENTS

The disclosure will be described more fully hereinafter with reference to the accompanying drawings, in which embodiments are shown. As those skilled in the art will appreciate, the described embodiments may be modified in various different ways, all without departing from the spirit or scope of the disclosure.

In order to clearly describe the disclosure, parts or portions that may be irrelevant to the description may be omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.

In the specification and the claims, the phrase “at least one of” is intended to include the meaning of “at least one selected from the group of” for the purpose of its meaning and interpretation. For example, “at least one of A and B” may be understood to mean “A, B, or A and B.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

will be understood that when an element such as a layer, film, region, area, substrate, plate, or constituent element is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Unless explicitly described to the contrary, “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, “connected” does not only mean when two or more elements are directly connected, but when two or more elements are indirectly connected through other elements, and when they are physically connected or electrically connected, and further, it may be referred to by different names depending on a position or function, and may also be referred to as a case in which respective parts that are substantially integrated are linked to each other.

Throughout the specification, when it is said that an element such as a wire, layer, film, region, area, substrate, plate, or constituent element “is extended (or extends) in a first direction or second direction”, this does not mean only a straight shape extending straight in the corresponding direction, but may mean a structure that substantially extends in the first direction or the second direction, is partially bent, has a zigzag structure, or extends while having a curved structure.

Both an electronic device (for example, a mobile phone, a TV, a monitor, a laptop computer, etc.) including a display device, or a display panel described in the specification, and an electronic device including a display device and a display panel manufactured by a manufacturing method described in the specification are not excluded from the scope of the specification.

Hereinafter, various embodiments and variations will be described in detail with reference to the drawings.

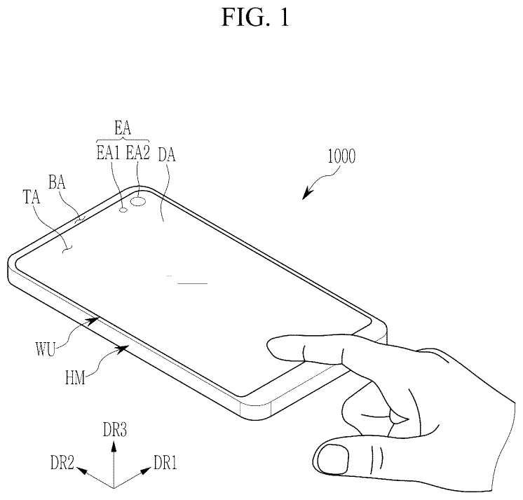

Hereinafter, a schematic structure of a display device will be described with reference to FIG. 1 to FIG. 3.

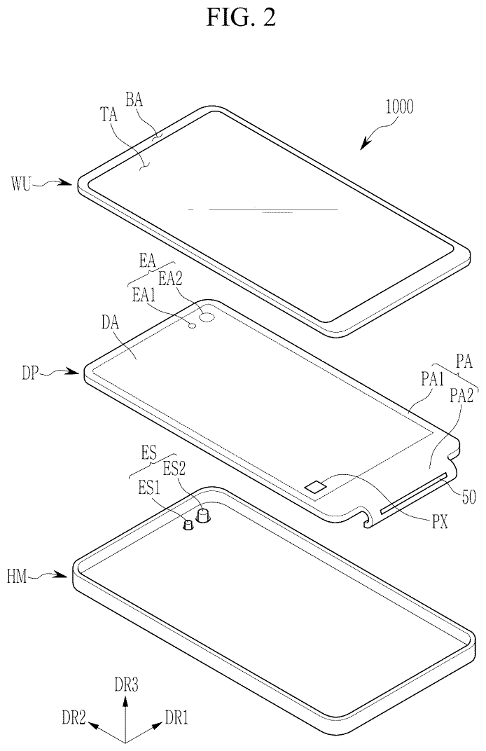

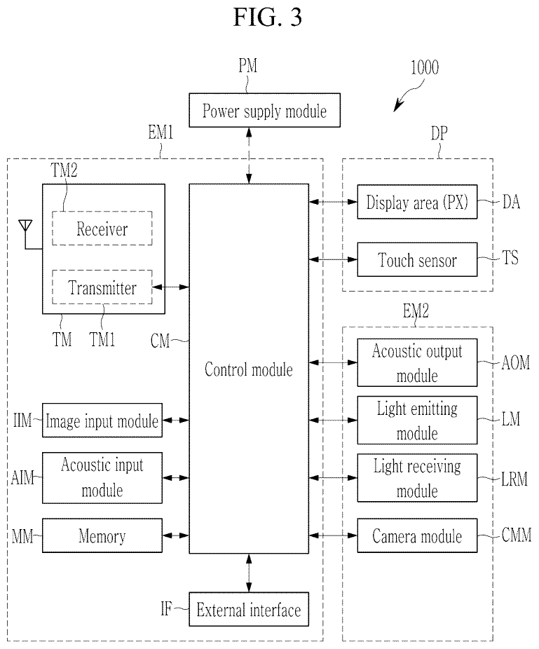

FIG. 1 illustrates a schematic perspective view of a use state of a display device according to an embodiment, FIG. 2 illustrates an exploded schematic perspective view of a display device according to an embodiment, and FIG. 3 illustrates a block diagram of a display device according to an embodiment.

Referring to FIG. 1, a display device 1000 according to an embodiment is a device for displaying a moving image or a still image, and may be used as a display screen of a portable electronic device such as a mobile phone, a smart phone, a tablet personal computer (PC), a mobile communication terminal, an electronic notebook, an electronic book, a portable multimedia player (PMP), a navigation device, and an ultra mobile PC (UMPC), and may be used as display screens of various products such as a television set, a laptop computer, a monitor, a billboard, and an Internet of things (IOT). The display device 1000 according to the embodiment may be used in a wearable device such as a smart watch, a watch phone, a glasses display, and a head mounted display (HMD). The display device 1000 according to the embodiment may be used as an instrument panel of a vehicle, a center information display (CID) disposed on a center fascia or dashboard of a vehicle, a room mirror display that replaces a side mirror of a vehicle, and a display disposed on the back of a front seat for entertainment for a rear seat of a vehicle. For better comprehension and ease of description, FIG. 1 illustrates a case in which that the display device 1000 is used for a smart phone.

The display device 1000 may display an image toward a third direction DR3 on a display surface parallel to each of a first direction DR1 and a second direction DR2. A display surface on which an image is displayed may correspond to a front surface of the display device 1000, and may correspond to a front surface of a cover window WU. An image may include a static image as well as a dynamic image.

In an embodiment, a front (or top) surface and a rear (or bottom) surface of each member are defined based on a direction in which an image is displayed. The front and rear surfaces may be opposite to each other in the third direction DR3, and a normal direction of each of the front and rear surfaces may be parallel to the third direction DR3. A separation distance in the third direction DR3 between the front and rear surfaces may correspond to a thickness of a display panel in the third direction DR3.

The display device 1000 according to the embodiment may detect a user's input (see a hand of FIG. 1) applied from the outside. The user's input may include various types of external inputs such as a part of the user's body, light, heat, or pressure. In the embodiment, the user's input is shown to be the user's hand applied to the front surface. However, the disclosure is not limited thereto. The user's input may be provided in various forms. The display device 1000 may sense the user's input applied to the lateral or rear surface of the display device 1000 according to the structure of the display device 1000.

Referring to FIG. 1 and FIG. 2, the display device 1000 may include the cover window WU, a housing HM, a display panel DP, and an optical element ES. In the embodiment, the cover window WU and the housing HM may be combined to form an appearance of the display device 1000.

The cover window WU may include an insulating panel. For example, the cover window WU may be made of glass, plastic, or a combination thereof.

A front surface of the cover window WU may define the front surface of the display device 1000. A transmission area TA may be an optically transparent area. For example, the transmission area TA may be an area having visible ray transmittance of about 90% or more.

A blocking area BA may define a shape of the transmission area TA. The blocking area BA may be adjacent to the transmission area TA, and may surround the transmission area TA. The blocking area BA may be an area having relatively low light transmittance compared with the transmission area TA. The blocking area BA may include an opaque material that blocks light. The blocking area BA may have a selectable color. The blocking area BA may be defined by a bezel layer provided separately from a transparent substrate defining the transmission area TA, or may be defined by an ink layer formed by being inserted into or coloring the transparent substrate.

The display panel DP may include a front surface that may include a display area DA and a non-display area PA. The display area DA may be an area in which a pixel operates to emit light according to an electrical signal. The non-display area PA of the display panel DP may include a driver 50.

In the embodiment, the display area DA may be an area that may include a pixel and in which an image is displayed, and may be an area in which a touch sensor is disposed at an upper side of the pixel in the third direction DR3 to sense an external input.

The transmission area TA of the cover window WU may at least partially overlap the display area DA of the display panel DP. For example, the transmission area TA may overlap the front surface of the display area DA, or may overlap at least a portion of the display area DA. Accordingly, a user may view an image through the transmission area TA, or may provide an external input based on the image. However, the disclosure is not limited thereto. For example, the display area DA may be divided into an area in which an image is displayed and an area in which an external input is sensed.

The non-display area PA of the display panel DP may at least partially overlap the blocking area BA of the cover window WU. The non-display area PA may be an area covered by the blocking area BA. The non-display area PA may be adjacent to the display area DA, and may surround the display area DA. No image is displayed in the non-display area PA, and a driving circuit or driving wire for driving the display area DA may be disposed therein. The non-display area PA may include a first peripheral area PA1 in which the display area DA is disposed at an outer side thereof, and a second peripheral area PA2 including the driver 50, a connection wire, and a bending area. In the embodiment of FIG. 2, the first peripheral area PA1 is disposed at three sides of the display area DA, and the second peripheral area PA2 is disposed on the other side of the display area DA.

In the embodiment, the display panel DP may be assembled in a flat state in which the display area DA and the non-display area PA are directed to the cover window WU. However, the disclosure is not limited thereto. A portion of the non-display area PA of the display panel DP may be bent. A portion of the non-display area PA faces the rear surface of the display device 1000, so that the blocking area BA shown on the front surface of the display device 1000 may be reduced, and in FIG. 2, the second peripheral area PA2 is bent, so that it may be assembled after disposing it on the rear surface of the display area DA.

The display panel DP may include a component area EA, for example, a first component area EA1 and a second component area EA2. The first component area EA1 and the second component area EA2 may be at least partially surrounded by the display area DA. The first component area EA1 and the second component area EA2 are illustrated as being spaced apart from each other, but are not limited thereto, and may be partially connected. The first component area EA1 and the second component area EA2 may be areas in which a component using infrared light, visible light, or sound is disposed thereunder.

Light emitting diodes, and pixel circuits that generate and transmit a light emitting current to each of the light emitting diodes, are formed in the display area DA. Here, one light emitting diode and one pixel circuit are referred to as a pixel PX. One pixel circuit portion and one light emitting diode are formed at a one-to-one ratio in the display area DA.

The first component area EA1 may include a transmission portion through which light or/and sound may pass and a display portion including pixels. The transmission portion is disposed between adjacent pixels, and is formed of a layer through which light or/and sound may pass. The transmission portion may be disposed between adjacent pixels, and in an embodiment, a layer that does not transmit light, such as a light blocking layer, may overlap the first component area EA1. The number of pixels (hereinafter also referred to as resolution) per unit area of the pixels (hereinafter also referred to as normal pixels) included in the display area DA may be the same as the number of pixels per unit area of the pixels (hereinafter also referred to as first component pixels) included in the first component area EA1.

The second component area EA2 may include an area (hereinafter also referred to as light transmission area) formed of a transparent layer to allow light to transmit therethrough, and the light transmission area may include an opening in which a layer in which a conductive layer or a semiconductor layer is not disposed and may include a light blocking material, for example, in which a pixel defining film and/or a light blocking layer overlaps a position corresponding to the second component area EA2, so that it may have a structure that does not block light. The number of pixels per unit area of the pixels (hereinafter also referred to as second component pixels) included in the second component area EA2 may be smaller than the number of pixels per unit area of the normal pixels included in the display area DA. As a result, the resolution of the second component pixel may be lower than that of the normal pixel.

Referring to FIG. 3 together with FIG. 1 and FIG. 2, the display panel DP may include the display area DA including a display pixel, and a touch sensor TS. The display panel DP may be viewed by a user from the outside through the transmissive area TA, by including the pixel, which is a component that displays an image. The touch sensor TS may be disposed on the pixel, and may sense external input applied from the outside. The touch sensor TS may sense an external input provided to the cover window WU.

Referring back to FIG. 2, the second peripheral area PA2 may include a bending portion. The display area DA and the first peripheral area PA1 may have a flat state substantially parallel to a plane defined by the first direction DR1 and the second direction DR2, and one side or a side of the second peripheral area PA2 may extend from the flat state through the bending part to have a flat state again. At least a portion of the second peripheral area PA2 may be bent to be assembled to be disposed on the rear surface side of the display area DA. Since at least a portion of the second peripheral area PA2 overlaps the display area DA in a plan view in case that assembled, the blocking area BA of the display device 1000 may be reduced. However, the disclosure is not limited thereto. For example, the second peripheral area PA2 may not be bent.

The driver 50 may be mounted on the second peripheral area PA2, mounted on the bending portion, or disposed at one of both sides of the bending portion. The driver 50 may be provided in a form of a chip.

The driver 50 may be electrically connected to the display area DA to transmit an electrical signal to the display area DA. For example, the driver 50 may provide data signals to pixels PX disposed in the display area DA. For example, the driver 50 may include a touch driving circuit, and may be electrically connected to the touch sensor TS disposed in the display area DA. The driver 50 may include various circuits in addition to the above-described circuits, or may be designed to provide various electrical signals to the display area DA.

A pad portion may be disposed at an end of the second peripheral area PA2, and the display device 1000 may be electrically connected to a flexible printed circuit board (FPCB) including a driving chip by the pad portion. Here, the driving chip disposed on the flexible printed circuit board may include various driving circuits for driving the display device 1000 or connectors for supplying of power. In an embodiment, instead of the flexible printed circuit board, a rigid printed circuit board (PCB) may be used.

The optical element ES may be disposed under or below the display panel DP. The optical element ES may include a first optical element ES1 overlapping the first component area EA1 and a second optical element ES2 overlapping the second component area EA2.

The first optical element ES1 may be an electronic element using light or sound. For example, the first optical element ES1 may be a sensor that receives and uses light such as an infrared sensor, a sensor that outputs and detects light or sound to measure a distance or recognize a fingerprint, a small-sized lamp that outputs light, a speaker that outputs sound, and the like within the spirit and the scope of the disclosure. In a case of an electronic element using light, light of various wavelength bands such as visible light, infrared light, and ultraviolet light may be used.

The second optical element ES2 may be at least one of a camera, an infrared camera (IR camera), a dot projector, an infrared illuminator, and a time-of-flight sensor (ToF sensor).

Referring to FIG. 3, the display device 1000 may include the display panel DP, a power supply module PM, a first electronic module EM1, and a second electronic module EM2. The display panel DP, the power supply module PM, the first electronic module EM1, and the second electronic module EM2 may be electrically connected to each other. FIG. 3 shows the display pixel and the touch sensor TS disposed in the display area DA of the display panel DP as an example.

The power supply module PM may supply power required for an overall operation of the display device 1000. The power supply module PM may include a battery module.

The first electronic module EM1 and the second electronic module EM2 may include various functional modules for operating the display device 1000. The first electronic module EM1 may be directly mounted on a motherboard electrically connected to the display panel DP, or mounted on a separate substrate to be electrically connected to the motherboard through a connector (not shown).

The first electronic module EM1 may include a control module CM, a wireless communication module TM, an image input module IIM, an audio input module AIM, a memory MM, and an external interface IF. Some or a number of the modules are not mounted on the motherboard, but may be electrically connected to the motherboard through the flexible printed circuit board connected thereto.

The control module CM may control the overall operation of the display device 1000. The control module CM may be a microprocessor. For example, the control module CM activates or deactivates the display panel DP. The control module CM may control other modules such as the image input module IIM or the audio input module AIM based on a touch signal received from the display panel DP.

The wireless communication module TM may transmit/receive a wireless signal with another terminal by using a Bluetooth or Wi-Fi line. The wireless communication module TM may transmit/receive a voice signal by using a general communication line. The wireless communication module TM may include a transmitter TM1 that modulates and transmits a signal to be transmitted, and a receiver TM2 that demodulates a received signal.

The image input module IIM may process an image signal to convert it into image data that may be displayed on the display panel DP. The audio input module AIM may receive an external audio signal inputted by a microphone in a recording mode, a voice recognition mode, and the like to convert it into electrical voice data.

The external interface IF may serve as an interface connected to an external charger, a wired/wireless data port, a card socket (for example, a memory card, a SIM/UIM card), and the like within the spirit and the scope of the disclosure.

The second electronic module EM2 may include an audio output module AOM, a light emitting module LM, a light receiving module LRM, and a camera module CMM, and at least some or a number of them are the optical elements ES and may be disposed on the rear surface of the display panel DP as shown in FIG. 1 and FIG. 2. The optical element ES may include the light emitting module LM, the light receiving module LRM, and the camera module CMM. The second electronic module EM2 may be directly mounted on the motherboard, mounted on a separate substrate to be electrically connected to the display panel DP through a connector (not shown), or electrically connected to the first electronic module EM1.

The audio output module AOM may convert audio data received from the wireless communication module TM or audio data stored in the memory MM to output it to the outside.

The light emitting module LM may generate and output light. The light emitting module LM may output infrared rays. For example, the light emitting module LM may include an LED element. For example, the light receiving module LRM may detect infrared rays. The light receiving module LRM may be activated in case that infrared rays of a selectable level or more are sensed. The light receiving module LRM may include a CMOS sensor. After the infrared light generated by the light emitting module LM is outputted, it may be reflected by an external subject (for example, a user's finger or face), and the reflected infrared light may be incident on the light receiving module LRM. The camera module CMM may capture an external image.

In the embodiment, the optical element ES may additionally include a light sensing sensor or a thermal sensing sensor. The optical element ES may sense an external object received through the front surface thereof, or may provide a sound signal such as a voice through the front surface to the outside. The optical element ES may include constituent elements, and is not limited to any one embodiment.

Referring back to FIG. 2, the housing HM may be combined with the cover window WU. The cover window WU may be disposed on the front surface of the housing HM. The housing HM may be combined with the cover window WU to provide a selectable accommodation space. The display panel DP and the optical element ES may be accommodated in the selectable accommodation space provided between the housing HM and the cover window WU.

The housing HM may include a material with relatively high rigidity. For example, the housing HM may include frames and/or plates made of glass, plastic, or metal, or a combination thereof. The housing HM may stably protect the components of the display device 1000 accommodated in an inner space thereof from external impact.

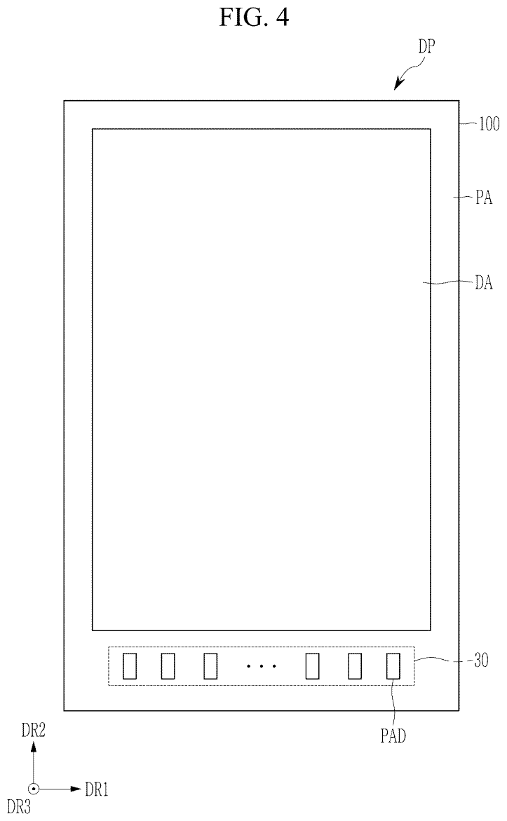

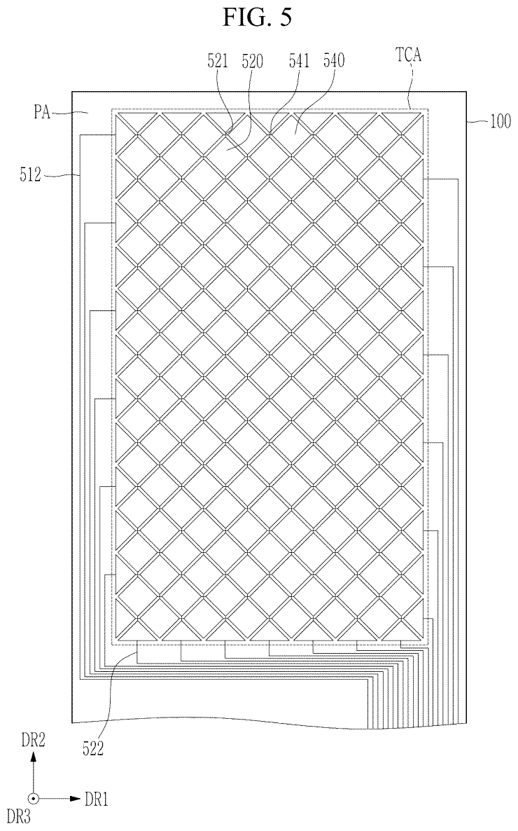

Hereinafter, a display panel of a display device according to an embodiment will be described with reference to FIG. 4 and FIG. 5.

FIG. 4 illustrates a schematic top plan view of a portion of a display panel according to an embodiment, and FIG. 5 illustrates a schematic top plan view of a sensing electrode of a display panel according to an embodiment.

Referring first to FIG. 4, the display panel DP of the display device 1000 according to the embodiment may include a substrate 100 and a pad portion 30.

The substrate 100 may be divided into the display area DA and the non-display area PA. The display area DA is an area in which light emitting diodes and pixel circuit portions generating and transmitting a light emitting current to each of the light emitting diodes are disposed to display an image, and the non-display area PA is an area in which no image is displayed. The non-display area PA may surround the display area DA. The non-display area PA may include the pad portion 30 in which a pad PAD for applying a driving signal to a pixel is disposed.

The pixel circuit portion included in a pixel (not shown) disposed in the display area DA and the light emitting diode are formed one-to-one, and the pixel circuit portions may be disposed in a matrix form, and the light emitting diode disposed thereon may be disposed in various forms.

Referring to FIG. 5, a sensing area TCA including sensing electrodes 520 and 540 may be disposed above the display area DA and above the light emitting diode so as to recognize a touch. The sensing area TCA may be an area in which the touch sensor TS is disposed.

In the non-display area PA, a signal line or a voltage line (for example, a driving voltage line, a driving low voltage line, or the like) for transmitting a signal or a voltage to the pixel disposed in the display area DA may be disposed, and the pad portion 30 connected to the signal line or the voltage line may be disposed. Sensing wires 512 and 522 may be further disposed in the non-display area PA. The sensing wires 512 and 522 may be connected to the sensing electrodes 520 and 540, and may be connected to some or a number of pads PAD of the pad portion 30.

The pad portion 30 is disposed in a portion of the non-display area PA, and may include pads PAD. A voltage, a signal, and the like may be applied to voltage lines (not shown) and the sensing wires 512 and 522 which are connected through the pads PAD in the display area DA. A flexible printed circuit board (FPCB) is attached to the pad portion 30 of the non-display area PA so that the flexible printed circuit board (FPCB) and the pad portion 30 may be electrically connected. The flexible printed circuit board (FPCB) and the pad portion 30 may be electrically connected to each other by an anisotropic conductive film.

As shown in FIG. 5, the sensing area TCA may include the sensing electrodes 520 and 540. The sensing electrodes 520 and 540 may include first sensing electrodes 520 and second sensing electrodes 540 that are electrically separated from each other.

In an embodiment, the first sensing electrodes 520 may be sensing input electrodes, and the second sensing electrodes 540 may be sensing output electrodes. However, they are not limited thereto, and the first sensing electrodes 520 may be sensing output electrodes, and the second sensing electrodes 540 may be sensing input electrodes.

The first sensing electrodes 520 and the second sensing electrodes 540 may be dispersed so as to not overlap each other in the sensing area TCA to be disposed in a mesh form. The first sensing electrodes 520 are disposed along one (the second direction DR2 in FIG. 5) of a column direction and a row direction, and the first sensing electrodes 520 are electrically connected to each other by a first sensing electrode connecting portion 521 (also referred to as a bridge). The second sensing electrodes 540 are disposed along the other (the first direction DR1 in FIG. 5) of a column direction and a row direction, and the second sensing electrodes 540 are electrically connected to each other by a second sensing electrode connecting portion 541.

The first sensing electrodes 520 and the second sensing electrodes 540 may be disposed on the same conductive layer. In an embodiment, the first sensing electrodes 520 and the second sensing electrodes 540 may be disposed on different conductive layers. Referring to FIG. 5, the first sensing electrode 520 and the second sensing electrode 540 may have a rhombic shape, but are not limited thereto, and may have a polygonal shape such as a quadrangular shape or a hexagonal shape, a circular shape, or an elliptical shape according to embodiments.

Referring to FIG. 5, first sensing electrodes 520 and second sensing electrodes 540 are shown as an integral structure of a rhombus, however, one rhombic structure has an opening and a structure in which linear structures are arranged or disposed in a mesh form. The opening may correspond to an area in which a light emitting diode emits light upward. In an embodiment, it may have a shape further including an extension to improve sensitivity of a sensing sensor.

The first sensing electrode 520 and the second sensing electrode 540 may be made of a transparent conductor or an opaque conductor. For example, the first sensing electrode 520 and the second sensing electrode 540 may include a transparent conductive oxide (TCO), and the transparent conductive oxide (TCO) may include at least one of an indium tin oxide (ITO), an indium zinc oxide (IZO), a zinc oxide (ZnO), carbon nanotubes (CNT), and graphene. The first sensing electrode 520 and the second sensing electrode 540 may include openings. The openings formed in the sensing electrodes 520 and 540 serve to allow light emitted from the light emitting diode to be directed to the front without interference.

In case that the first sensing electrode 520 and the second sensing electrode 540 are disposed on the same layer, one of the first sensing electrode connecting part 521 and the second sensing electrode connecting part 541 may be disposed on the same layer as the first sensing electrode 520 and the second sensing electrode 540, and the other thereof may be disposed on a different layer from the first sensing electrode 520 and the second sensing electrode 540. As a result, the first sensing electrodes 520 and the second sensing electrodes 540 may be electrically separated. The sensing electrode connecting part disposed on the different layer may be disposed on upper or lower layers of the first sensing electrode 520 and the second sensing electrode 540, and in an embodiment to be described below, an embodiment in which the sensing electrode connecting part is disposed on the lower layer, for example, a layer closer to the substrate, will be described.

Sensing wires 512 and 522 respectively connected to the first sensing electrodes 520 and the second sensing electrodes 540 are disposed in the non-display area PA. The first sensing wires 512 may be connected to the second sensing electrodes 540 disposed in the first direction DR1, and the second sensing wires 522 may be connected to the first sensing electrodes 520 disposed in the second direction DR2. In an embodiment, the first sensing wire 512 and the second sensing wire 522 may be electrically connected to a portion of the pad PAD included in the pad portion 30 of FIG. 4.

FIG. 5 illustrates a mutual-cap type of sensing portion that senses a touch by using two sensing electrodes 520 and 540. However, in an embodiment, a self-cap type of sensing portion that senses a touch by using only one sensing electrode may be formed.

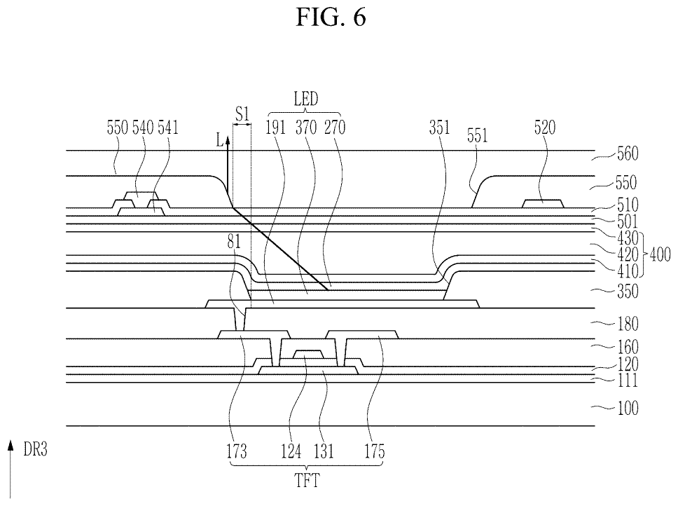

Hereinafter, a display device according to an embodiment will be further described with reference to FIG. 6, focusing on a schematic cross-sectional view in the display area DA.

FIG. 6 illustrates a schematic cross-sectional view of a portion of a display area in a display device according to an embodiment.

As shown in FIG. 6, the display device 1000 according to an embodiment may include the substrate 100, and a transistor TFT that is disposed on the substrate 100 and may include a semiconductor 131, a gate electrode 124, a source electrode 173, and a drain electrode 175.

For example, a buffer layer 111 is disposed on the substrate 100, the semiconductor 131 is disposed on the buffer layer 111, a gate insulating film 120 is disposed on the semiconductor 131, and the gate electrode 124 is disposed on the gate insulating film 120. An interlayer insulating film 160 is disposed on the gate electrode 124, the source electrode 173 and the drain electrode 175 are disposed on the interlayer insulating film 160, and an organic film 180 is disposed thereon. The source electrode 173 and the drain electrode 175 are respectively connected to a portion (a source area or a drain area) of the semiconductor 131 through an opening disposed in the gate insulating film 120 and the interlayer insulating film 160. A pixel electrode 191 is disposed on the organic film 180, and a pixel defining film 350 including a pixel opening 351 overlapping at least a portion of the pixel electrode 191 is disposed on the pixel electrode 191. A light emitting layer 370 is disposed within the pixel opening 351 of the pixel defining film 350 and on the pixel electrode 191. A common electrode 270 is disposed on the pixel defining film 350 and the light emitting layer, and an encapsulation layer 400 is disposed on the common electrode. Here, the pixel electrode 191, the light emitting layer 370, and the common electrode 270 may form the light emitting diode LED.

A lower sensing insulating layer 501, a first sensing insulating layer 510, the sensing electrodes 520 and 540, and the sensing electrode connecting portion 541 may be disposed on the encapsulation layer 400 for touch sensing. The display device may further include a first insulating layer 550 and a second insulating layer 560 disposed above the sensing area TCA.

The structure of FIG. 6 as described above will be described in detail below.

The substrate 100 may include a material having a rigid characteristic, such as glass, or a flexible material that may be bent, such as plastic and polyimide. The buffer layer 111 for flattening a surface of the substrate 100 and blocking impure elements from penetrating may be further disposed on the substrate 100. The buffer layer 111 may include an inorganic material, for example, an inorganic insulation material such as a silicon nitride (SiNₓ), a silicon oxide (SiOₓ), or a silicon oxynitride (SiOₓN_{y}). In an embodiment, the buffer layer 111 may have a single-layered or multi-layered structure including one or more inorganic insulating materials. A barrier layer (not shown) may be further disposed on the substrate 100. The barrier layer may be disposed between the substrate 100 and the buffer layer 111. The barrier layer may include an inorganic insulation material such as a silicon nitride (SiNₓ), a silicon oxide (SiOₓ), and a silicon oxynitride (SiOₓN_{y}). The barrier layer may have a single-layered or multi-layered structure including one or more inorganic insulating materials.

The semiconductor 131 may be disposed on the substrate 100. The semiconductor 131 may include one of an amorphous silicon, a polycrystalline silicon, and an oxide semiconductor. For example, the semiconductor 131 may include a low temperature polycrystalline silicon (LTPS), or an oxide semiconductor including at least one of zinc (Zn), indium (In), gallium (Ga), tin (Sn), and a mixture thereof. For example, the semiconductor 131 may include an indium-gallium-zinc oxide (IGZO). The semiconductor 131 may include a channel area, a source area, and a drain area that are classified according to whether or not impurity doping is performed. The source area and the drain area may have a conductive characteristic corresponding to a conductor.

The gate insulating film 120 may cover the semiconductor 131 and the substrate 100. The gate insulating film 120 may include an inorganic insulation material such as a silicon nitride (SiNₓ), a silicon oxide (SiOₓ), and a silicon oxynitride (SiOₓN_{y}). The gate insulating film 120 may have a single-layered or multi-layered structure including one or more inorganic insulating materials.

The gate electrode 124 may be disposed on the gate insulating film 120. The gate electrode 124 may include a metal such as copper (Cu), molybdenum (Mo), aluminum (Al), silver (Ag), chromium (Cr), tantalum (Ta), and titanium (Ti), or a metal alloy thereof. The gate electrode 124 may be formed as a single layer or a multilayer. An area of the semiconductor 131 that overlaps the gate electrode 124 in a plan view may be a channel area. The interlayer insulating film 160 may cover the gate electrode 124 and the gate insulating film 120. The interlayer insulating film 160 may include an inorganic insulating material such as a silicon nitride (SiNₓ), a silicon oxide (SiOₓ), and a silicon oxynitride (SiOₓN_{y}). The interlayer insulating film 160 may have a single-layered or multi-layered structure including one or more inorganic insulating materials.

The source electrode 173 and the drain electrode 175 may be disposed on the interlayer insulating film 160. The source electrode 173 and the drain electrode 175 are respectively connected to the source area and the drain area of the semiconductor 131 by openings formed in the interlayer insulating film 160 and the gate insulating film 120. Accordingly, the semiconductor 131, the gate electrode 124, the source electrode 173, and the drain electrode 175, which are described above, form a transistor TFT. In an embodiment, the transistor TFT may include only the source and drain areas of the semiconductor 131 instead of the source electrode 173 and the drain electrode 175.

The source electrode 173 and the drain electrode 175 may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta), or a metal alloy thereof. The source electrode 173 and the drain electrode 175 may be formed as a single layer or a multilayer. The source electrode 173 and the drain electrode 175 according to an embodiment may be formed of a triple layer including an upper layer, an intermediate layer, and a lower layer, wherein the upper layer and the lower layer may include titanium (Ti), and the intermediate layer may include aluminum (Al).

The organic film 180 may be disposed on the source electrode 173 and the drain electrode 175. The organic film 180 covers the source electrode 173, the drain electrode 175, and the interlayer insulating film 160. The organic film 180 is for planarizing the surface of the substrate 100 provided with the transistor TFT, and may be an organic insulation film, and may include one or more of a polyimide, a polyamide, an acryl resin, a benzocyclobutene, and a phenol resin.

The pixel electrode 191 may be disposed on the organic film 180. The pixel electrode 191 is also referred to as an anode electrode, and may be formed as a single layer or a multilayer that may include a transparent conductive oxide film or a metal material. The transparent conductive oxide film may include an indium tin oxide (ITO), a poly-ITO, an indium zinc oxide (IZO), an indium gallium zinc oxide (IGZO), and an indium tin zinc oxide (ITZO). The metal material may include silver (Ag), molybdenum (Mo), copper (Cu), gold (Au), and aluminum (Al).

The organic film 180 may include an opening 81 exposing the drain electrode 175. The drain electrode 175 and the pixel electrode 191 may be physically and electrically connected to each other through the opening 81 of the organic film 180. Accordingly, the pixel electrode 191 may receive an output current to be transmitted from the drain electrode 175 to the light emitting layer 370.

The pixel defining film 350 may be disposed on the pixel electrode 191 and the organic film 180. The pixel defining film 350 may include the pixel opening 351 overlapping at least a portion of the pixel electrode 191. The pixel opening 351 may overlap a central portion of the pixel electrode 191, and may not overlap an edge of the pixel electrode 191. Accordingly, a size of the pixel opening 351 may be smaller than that of the pixel electrode 191. The pixel defining film 350 may partition a formation position of the light emitting layer 370 so that the emission layer 370 may be disposed on a portion where an upper surface of the pixel electrode 191 is exposed. The pixel defining film 350 may be an organic insulating film including one or more of a polyimide, a polyamide, an acryl resin, a benzocyclobutene, and a phenol resin, and in an embodiment, the pixel defining film 350 may be formed as a black pixel defining layer (BPDL) including a black color pigment.

The light emitting layer 370 may be disposed within the pixel opening 351 partitioned by the pixel defining film 350. The light emitting layer 370 may include an organic material that emits red, green, and blue light. The light emitting layer 370 that emits red, green, and blue light may include a low molecular weight or high molecular weight organic material. Although the light emitting layer 370 is illustrated as a single layer in FIG. 6, actually, auxiliary layers such as an electron injection layer, an electron transport layer, a hole transport layer, and a hole injection layer may be included above and below the light emitting layer 370, and a hole injection layer and a hole transport layer may be disposed under or below the light emitting layer 370, while an electron transport layer and an electron injection layer may be disposed on the light emitting layer 370.

The common electrode 270 may be disposed on the pixel defining film 350 and the light emitting layer 370. The common electrode 270 is also referred to as a cathode, and may be formed of a transparent conductive layer including an indium tin oxide (ITO), an indium zinc oxide (IZO), an indium gallium zinc oxide (IGZO), and an indium tin zinc oxide (ITZO). The common electrode 270 may have a translucent characteristic, and, may form a micro-cavity together with the pixel electrode 191. According to the structure of the micro-cavity, light with a given wavelength is emitted upward by a gap and characteristic between electrodes at both ends thereof, and as a result, red, green, or blue colors may be displayed.

The encapsulation layer 400 may be disposed on the common electrode 270. The encapsulation layer 400 may include at least one inorganic film and at least one organic film. In an embodiment, the encapsulation layer 400 may include a first inorganic encapsulation layer 410, an organic encapsulation layer 420, and a second inorganic encapsulation layer 430. However, this is only an example, and the number of inorganic and organic films forming the encapsulation layer 400 may be variously changed. The first inorganic encapsulation layer 410, the organic encapsulation layer 420, and the second inorganic encapsulation layer 430 may cover the display area DA, and may be disposed in a portion of the non-display area NA. In an embodiment, the organic encapsulation layer 420 may be disposed around the display area DA, and the first inorganic encapsulation layer 410 and the second inorganic encapsulation layer 430 may be disposed up to the non-display area PA. The encapsulation layer 400 is to protect the light emitting diode LED from moisture or oxygen that may be introduced from the outside, and one-end portions of the first inorganic encapsulation layer 410 and the second inorganic encapsulation layer 430 may directly contact each other.

The lower sensing insulating layer 501 may be disposed on the encapsulation layer 400. The lower sensing insulating layer 501 may be formed as an inorganic insulating film, and an inorganic material included in the inorganic insulating film may be at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride. In an embodiment, the lower sensing insulating layer 501 may be omitted.

The sensing electrode connecting portion 541, the first sensing insulating layer 510, and the sensing electrodes 520 and 540 may be disposed on the lower sensing insulating layer 501. One of the first sensing electrode connecting portion 521 and the second sensing electrode connecting portion 541 may be disposed on the same layer as the sensing electrodes 520 and 540, and the other thereof may be disposed on a different layer from the sensing electrodes 520 and 540. Hereinafter, an example in which the second sensing electrode connecting portion 541 is disposed on a different layer from the sensing electrodes 520 and 540 will be described.

The sensing electrode connecting portion 541, the first sensing insulating layer 510, and the sensing electrodes 520 and 540 may form a sensing sensor. The sensing sensor may be classified into a resistive type, a capacitive type, an electro-magnetic type, an optical type, and the like within the spirit and the scope of the disclosure. The sensing sensor according to the embodiment may use a capacitance type of sensor.

The sensing electrode connecting portion 541 may be disposed on the lower sensing insulating layer 501, and the first sensing insulating layer 510 may be disposed on the lower sensing insulating layer 501 and the second sensing electrode connecting portion 541. The first sensing insulating layer 510 may include an inorganic insulating material or an organic insulating material. The inorganic insulating material may include at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride. The organic insulating material may include at least one of an acryl-based resin, a methacrylic-based resin, a polyisoprene, a vinyl-based resin, an epoxy-based resin, a urethane-based resin, a cellulose-based resin, and a perylene-based resin.

The sensing electrodes 520 and 540 may be disposed on the first sensing insulating layer 510. The sensing electrodes 520 and 540 may include first sensing electrodes 520 and second sensing electrodes 540. The first sensing electrode 520 and the second sensing electrode 540 may be electrically insulated from each other. The first sensing insulating layer 510 may include an opening exposing an upper surface of the second sensing electrode connecting part 541, and the second sensing electrode connecting part 541 may be connected to the second sensing electrode 540 through an opening of the first sensing insulating layer 510 to electrically connect two second sensing electrodes 540 adjacent to each other. The first sensing electrode connecting portion 521 for connecting the first sensing electrode 520 may be formed on the same layer as the first sensing electrode 520 and the second sensing electrode 540.

The sensing electrodes 520 and 540 may include a conductive material having good conductivity. For example, the sensing electrodes 520 and 540 may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta), or a metal alloy thereof. The sensing electrodes 520 and 540 may be formed as a single layer or a multilayer. The sensing electrodes 520 and 540 may include openings so that light emitted from the light emitting diode is emitted upward without interference. In an embodiment, the sensing electrodes 520 and 540 may be formed of a triple layer including an upper layer, an intermediate layer, and a lower layer, wherein the upper layer and the lower layer may include titanium (Ti), and the intermediate layer may include aluminum (Al).

A first insulating layer 550 is disposed on the sensing electrodes 520 and 540 and the first sensing insulating layer 510. The first insulating layer 550 may include a light transmitting organic insulating material having a low refractive index. For example, the first insulating layer 550 may include an acrylic resin, a polyimide resin, a polyamide resin, and Alq3 [tris(8-hydroxyquinolinato)aluminum]. The first insulating layer 550 may have a relatively smaller refractive index than a second insulating layer 560, which will be described later. For example, the first insulating layer 550 may have a refractive index of 1.40 to 1.59.

The first insulating layer 550 may include an opening 551. The opening 551 means a portion in which the first sensing insulating layer 510 is not covered by the first insulating layer 550. The opening 551 of the first insulating layer 550 may overlap the pixel opening 351 in a plan view, and a boundary of the pixel opening 351 and a boundary of the opening 551 of the first insulating layer 550 have a separation distance S1 in a plan view. As a result, the pixel opening 351 may be disposed within the opening 551 of the first insulating layer 550 in a plan view, and a planar size of the opening 551 of the first insulating layer 550 may be larger than that of the pixel opening 351.

The separation distance S1 between the pixel opening 351 and the opening 551 of the first insulating layer 550 means a shortest distance between an edge of the pixel opening 351 and an edge of the opening 551. An edge of the pixel opening 351 may mean a planar shape formed by a lower portion of an edge of the pixel defining film 350 in contact with the pixel electrode 191. An edge of the opening 551 of the first insulating layer 550 may mean a planar shape formed by a lower portion of the edge of the first insulating layer 550 that contacts the first sensing insulating layer 510.

The separation distance S1 between the pixel opening 351 and the opening 551 of the first insulating layer 550 may not be constant depending on the position of the pixel opening 351 and the opening 551.

The second insulating layer 560 may be disposed on the first sensing insulating layer 510 and the first insulating layer 550. The second insulating layer 560 may include a light transmitting organic insulating material having a high refractive index. The second insulating layer 560 may have a relatively larger refractive index than the first insulating layer 550. For example, the second insulating layer 560 may have a refractive index of 1.60 to 1.80.

The second insulating layer 560 may also be disposed in the opening 551 of the first insulating layer 550. The second insulating layer 560 may contact the side surface of the first insulating layer 550 within the opening 551. Since the second insulating layer 560 is also disposed on the upper surface of the first insulating layer 550, the upper surface of the first insulating layer 550 and the second insulating layer 560 are in contact with each other.

By including the first insulating layer 550 including the opening 551 of the first insulating layer 550 and the second insulating layer 560 disposed in the opening 551 of the first insulating layer 550 on the front surface of the light emitting layer 370, it is possible to improve the light emitting efficiency in the front direction. For example, at least some of the light generated from the light emitting diode LED may be totally reflected or reflected at the interface between the first insulating layer 550 and the second insulating layer 560 to be condensed to the front.

The improvement in light emitting efficiency in the front direction is described as follows.

Light L generated from the light emitting layer 370 is emitted in various directions, and is incident to the first insulating layer 550 and the second insulating layer 560 at various incident angles. Some of the light L is incident on the boundary surface between the first insulating layer 550 and the second insulating layer 560, and is totally reflected or reflected due to the difference in refractive index between the first insulating layer 550 and the second insulating layer 560. For example, in case that the incident angle of the light L incident on the boundary surface is larger than the critical angle, the incident light L may be totally reflected on the boundary surface between the first insulating layer 550 and the second insulating layer 560. In case that the light L incident on the second insulating layer 560 having a relatively high refractive index proceeds to the first insulating layer 550 having a relatively small refractive index and the incident angle is larger than a certain angle (a critical angle), total reflection occurs at the boundary surface between the first insulating layer 550 and the second insulating layer 560. In this way, the direction of the light L that should proceed to the side surface is changed to the front surface at the boundary surface between the first insulating layer 550 and the second insulating layer 560, thereby improving luminance at the front surface and improving the light emitting efficiency.

Although not shown, in the display device, a polarization layer including a linear polarizer and a retardation plate may be disposed, and a cover window may be further disposed on the polarization layer. An adhesive layer may be further disposed between the polarization layer and the cover window.

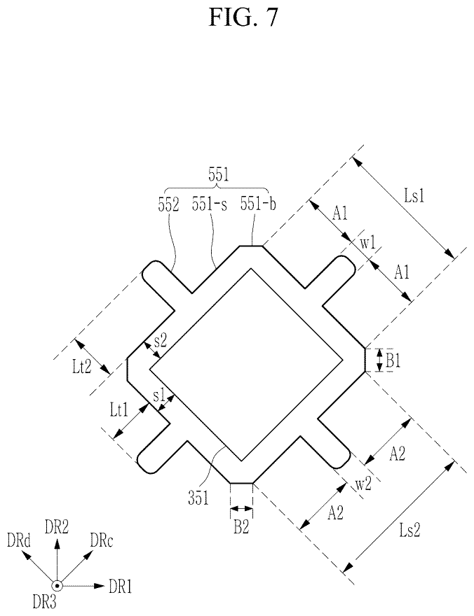

Hereinafter, planar structures of the pixel opening 351 and the opening 551 of the first insulating layer 550 of the display device will be described in detail with reference to FIG. 7.

FIG. 7 illustrates a schematic top plan view of a portion of a display device according to an embodiment.

FIG. 7 illustrates only the pixel opening 351 and the opening 551 of the first insulating layer 550 of the display device, but the light emitting layer 370 is disposed within the pixel opening 351 of the pixel defining film 350, and the second insulating layer 560 is disposed within the opening 551 of the first insulating layer 550. One opening disposed on the first insulating layer 550 may include at least one protruding extension 552.

The opening 551 of the first insulating layer 550 overlaps the pixel opening 351. The pixel opening 351 may be disposed only inside the opening 551 of the first insulating layer 550 in a plan view. An area and size of the opening 551 of the first insulating layer 550 may be larger than an area and size of the pixel opening 351.

The pixel opening 351 may have a polygonal shape in a plan view, and according to the embodiment shown in FIG. 7, the pixel opening 351 has a rhombic shape. In an embodiment, at least one of corners of the polygonal shape thereof may have a chamfered structure, and the chamfered corner may be chamfered straight or curved. However, the planar shape of the pixel opening 351 is not limited thereto, and may be variously changed. For example, the planar shape of the pixel opening 351 may have various polygonal shapes, or may be circular or elliptical.

A planar shape of the opening 551 of the first insulating layer 550 may be similar to the planar shape of the pixel opening 351. The opening 551 of the first insulating layer 550 is larger than the pixel opening 351 in a plan view, and an edge of the opening 551 may be disposed outside an edge of the pixel opening 351.

The opening 551 of the first insulating layer 550 is divided into a main portion and an extension 552 protruding from the main portion, and the main portion is divided into a side 551-s and a chamfer portion 551-b.

The side 551-s of the opening 551 of the first insulating layer 550, the side 551-s is disposed substantially parallel to each edge of the pixel opening 351 in a plan view. The main portion of the opening 551 of the first insulating layer 550 may have a polygonal shape similar to the planar shape of the pixel opening 351, and has a chamfered corner structure to include the chamfer portion 551-b.

The opening 551 of the first insulating layer 550 may include extensions 552 protruding from respective central portions of sides 551-s. Two of the expansions 552 extend in a fourth direction DRc forming an oblique line with the first direction DR1 and second direction DR2, and the other two thereof extend in a fifth direction DRd that forms an oblique line with the first and second directions DR1 and DR1 and is different from the fourth direction DRc. Each extension 552 may be disposed at a center of each side 551-s, and may be disposed away from the center according to embodiments.

In the embodiment of FIG. 7, the two extensions 552 extending in the fourth direction DRc and the two extensions 552 extending in the fifth direction DRd are on a straight line, respectively. However, in an embodiment, the extensions 552 protruding in the same direction may not be disposed on a straight line.

In the opening 551 of the first insulating layer 550, the fourth direction DRc and the fifth direction DRd, which are the directions in which respective extensions 552 protrude, may form an angle of about 45 degrees with the first direction DR1 and/or the second direction DR2, and in an embodiment, they may form an angle of greater than or equal to about 35 degrees and less than or equal to about 55 degrees therewith.

Each extension 552 may have a shape in which a length Lt1 or Lt2 is longer than a width w1 or w2, and may have a structure in which the width w1 or w2 gradually decreases according to embodiments. In the embodiment in which the width gradually decreases, a value of the width w1 or w2 of each extension 552 may be a width at a point where the side 551-s and the extension 552 meet. An end of each of the extensions 552 may have a shape of a convex curved line.

In FIG. 7, the widths w1 and w2 and the lengths Lt1 and Lt2 of the two extensions 552 (hereinafter also referred to as first extensions) extending in the fourth direction DRc and the two extensions 552 (hereinafter also referred to as second extensions) extending in the fifth direction DRd are shown, respectively, and this means that the widths and lengths of respective extensions 552 may be the same, or, in an embodiment, the first extension and the second extension may have different widths and lengths.

According to FIG. 7, a total of four extensions 552 are included, and the four first extensions have a structure protruding in an x-shape, so it is also referred to as an x-shaped opening.

The main portion of the opening 551 of the first insulating layer 550 is divided into the side 551-s and the chamfer portion 551-b, and the side 551-s may be divided into two sides (hereinafter also referred to as first sides) that extend in the fifth direction DRd and are spaced apart from each other and two sides (hereinafter also referred to as second sides) that extend in the fourth direction DRc and are spaced apart from each other substantially parallel to each other. Here, a total length of the first side may be Ls1, and a total length of the second side may be Ls2. A length excluding the width w1 of the first protrusion of the first side is 2A1, and a length excluding the width w2 of the second protrusion of the second side is 2A2. The lengths of the first side and the second side may be the same, or may be different according to embodiments.

A first distance s1 may be provided between the first side of the opening 551 of the first insulating layer 550 and an edge of the pixel opening 351 adjacent thereto, and a second distance s2 may be provided between the second side of the opening 551 of the first insulating layer 550 and an edge of the pixel opening 351 adjacent thereto. Here, the first distance s1 and the second distance s2 may not be the same. For example, the distances s1 between the first sides that extend in the same direction and are spaced apart from each other to face each other and the edges of the pixel opening 351 adjacent thereto may be the same, and the distances s2 between the second sides that face each other and the edges of the pixel opening 351 adjacent thereto may be the same.

The chamfer portion 551-b is disposed between the first side and the second side, respectively. An edge extending in the second direction DR2 (hereinafter referred to as a first edge) has a B1 length, and an edge extending in the first direction DR1 (hereinafter referred to as a second edge) has a B2 length. Respective chamfer portions 551-b may have the same length, or may have different lengths according to embodiments.

Since the shape of the opening 551 of the first insulating layer 550 shown in FIG. 7 is one example, the disposition angle, length, shape, and the like thereof may be variously changed.

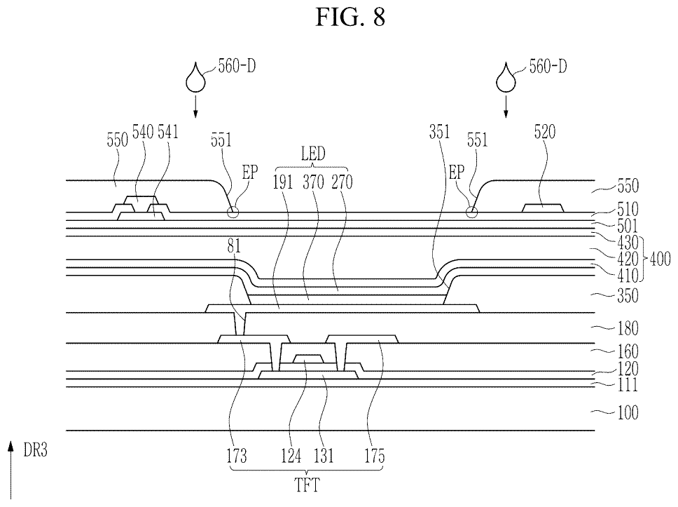

The opening 551 of the first insulating layer 550 shown in FIG. 7 has the first extensions 552, and the extensions 552 may have a long extending shape according to embodiments. Therefore, in case that the second insulating layer 560 is formed, a dripped material forming the second insulating layer 560 may be well filled up to the edges and corners of the opening 551 of the first insulating layer 550 due to the capillary phenomenon. This will be described in more detail with reference to FIG. 8.

FIG. 8 illustrates a schematic cross-sectional view of a step of a manufacturing process of a display device according to an embodiment.

FIG. 8 illustrates forming the first insulating layer 550 having the opening 551, and dripping and curing droplets 560-D of a material forming the second insulating layer 560 to form the second insulating layer 560.

The droplets 560-D dripped on the surface of the first insulating layer 550 may move toward the opening 551 of the first insulating layer 550 and fill the opening 551 of the first insulating layer 550, but in case that the expansions 552 are not formed in the opening 551 of the first insulating layer 550, the droplets 560-D may not sufficiently fill the side 551-s or an end portion EP of the chamfer portion 551-b of the opening 551 of the first insulating layer 550, by example the corner portion between two adjacent edges extending in different directions.

As described above, the material for forming the second insulating layer 560 may not be disposed at the edge portion of the opening 551 of the first insulating layer 550, and as a result, the second insulating layer 560 may not be uniformly formed on the substrate as a whole. In order to uniformly form the second insulating layer 560, a method of thickly forming the second insulating layer 560 by increasing the dripping amount of the droplets 560-D may be considered, but this may increase the thickness of the display device. Another problem due to the thickness may occur in a subsequent process, and in a case of foldable products, folding characteristics or impact resistance characteristics may be deteriorated.

However, in case that the expansion 552 is formed in the opening 551 of the first insulating layer 550, the opening 551 of the first insulating layer 550 may be filled up as the droplet 560-D flows into an additional space formed by the expansion 552. For example, the long extending extension 552 may serve to diffuse the material layer forming the second insulating layer 560 flowing toward the edge of the opening 551 of the first insulating layer 550 by capillary action.

Therefore, according to the display device according to an embodiment, the material for forming the second insulating layer 560 may be uniformly disposed in the openings 551 of the first insulating layer 550, and through this, the second insulating layer 560 may be uniformly formed with a thin thickness. As such, the overall thickness of the display device may be reduced, problems occurring in subsequent processes may be solved, and it may be stably used in foldable products.

According to the display device according to an embodiment, in case that the thickness of the first insulating layer 550 is in a range of about 2 μm to about 4 μm, for example, in a range of about 2.3 μm to about 3.5 μm, the thickness of the second insulating layer 560 may be in a range of about 9 μm to about 11 μm, and the second insulating layer 560 is not unevenly filled in the opening of the first insulating layer 550, so that the surface of the second insulating layer 560 may be flat. Generally, unlike the display device according to an embodiment, in case that the opening 551 of the first insulating layer 550 does not include the extension 552, and in case that the thickness of the first insulating layer 550 is in a range of about 2 μm to about 4 μm, for example in a range of about 2.3 μm to about 3.5 μm, since the second insulating layer 560 should have a thickness of about 25 μm or more so that the second insulating layer 560 does not unevenly fill the openings of the first insulating layer 550 and the surface of the second insulating layer 560 may be flat, it can be seen that a large difference occurs in the thicknesses.

Capillary pressure (Pc) may be defined by Equation 1 below.

$$Rc = γ ( \frac{1}{Rx} + \frac{1}{R y} ) \qquad ( Equation 1 )$$

Here, γ is a surface tension, Rx is a variable related to a shape of the liquid-filled portion, for example, a value that increases as it more resembles a circular shape, and Ry is a value that increases as a depth of the liquid-filled portion increases.

Therefore, as the liquid-filled portion resembles a circular shape, the capillary pressure decreases, thereby making it difficult to fill with liquid. For example, as the shape of the opening 551 of the first insulating layer 550 resembles a circular shape, the material for forming the second insulating layer 560 may not uniformly fill the opening 551. Accordingly, in the embodiment, the opening 551 of the first insulating layer 550 may be formed to have a polygonal shape.

Hereinafter, characteristics of the structure of the opening 551 of the first insulating layer 550 having the structure shown in FIG. 7 will be described.

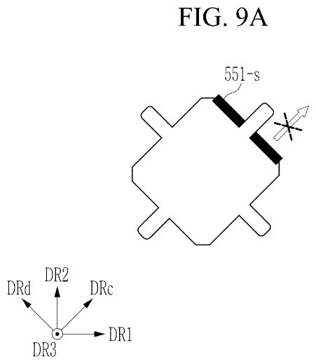

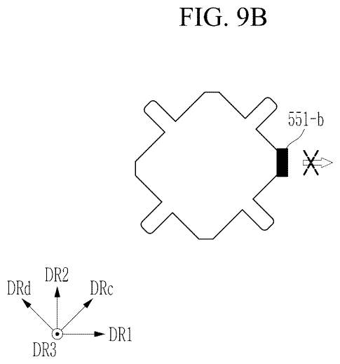

FIG. 9 to FIG. 17 illustrate features of the embodiment of FIG. 7.

First, the roles of the side 551-s and the chamfer portion 551-b of the opening 551 of the first insulating layer 550 according to the embodiment of FIG. 7 are separately illustrated in FIG. 9.

In FIG. 9 (A), the role of the side 551-s of the opening 551 is illustrated. Since the sides 551-s disposed in the fifth direction DRd allow light emitted from the light emitting layer disposed within the pixel opening 351 to be refracted at the sides 551-s and emitted to the front, in case that a viewing angle is small with respect to an azimuth angle of the fourth direction DRc, an amount of light is increased by the light refracted to the front, and the amount of light gradually decreases as the viewing angle increases. In FIG. 9 (A), as the light is refracted to the front from the side 551-s, it is briefly illustrated by an arrow and a dotted x mark where the light propagates less at a large viewing angle with respect to the azimuth angle of the fourth direction DRc. According to the side 551-s disposed in the fourth direction DRc among the openings 551, in case that the viewing angle of the light is small with respect to the azimuth angle of the fifth direction DRd, the amount of light may be increased by the light refracted to the front, and the amount of light may be gradually decreased as the viewing angle increases.

In FIG. 9 (B), the role of the chamfer portion 551-b of the opening 551 is illustrated. Since the chamfer portion 551-b disposed in the second direction DR2 allows light emitted from the light emitting layer disposed within the pixel opening 351 to be refracted at the chamfer portion 551-b and emitted to the front, in case that a viewing angle is small with respect to an azimuth angle of the first direction DR1, an amount of light is increased by the light refracted to the front, but the amount of light relatively rapidly decreases as the viewing angle increases. In FIG. 9 (B), as the light is refracted to the front from the chamfer portion 551-b, it is briefly illustrated by an arrow and a dotted x mark where the light propagates less at a large viewing angle with respect to the azimuth angle of the first direction DR1. According to the chamfer portion 551-b disposed in the first direction DR1 among the openings 551, in case that the viewing angle of the light is small with respect to the azimuth angle of the second direction DR2, the amount of light may be increased by the light refracted to the front, but the amount of light may be relatively rapidly decreased as the viewing angle increases.

The side 551-s and the chamfer portion 551-b of the opening 551 of the first insulating layer 550 allow light to be emitted to the front, but the extension 552 does not emit light to the front.

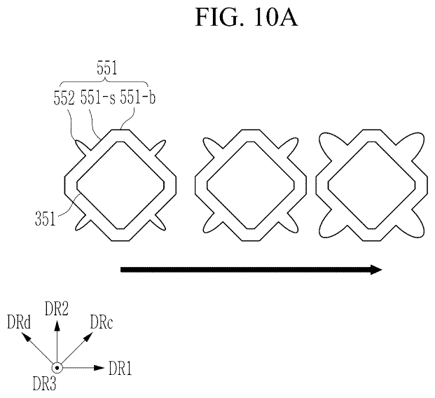

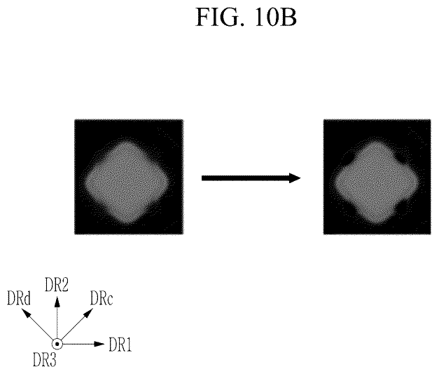

In FIG. 10, characteristics according to the width of the expansion 552 are illustrated.

Referring to FIG. 10 (A), an embodiment in which the width of the expansion 552 gradually increases is illustrated.

In FIG. 10 (B), a light emitting area is photographed, and it can be seen that efficiency of light provided to the front from a portion corresponding to the expansion 552 is low, and as the extension 552 increases, it can be seen that a degree to which the portion corresponding to the extension 552 is concavely displayed further increases.

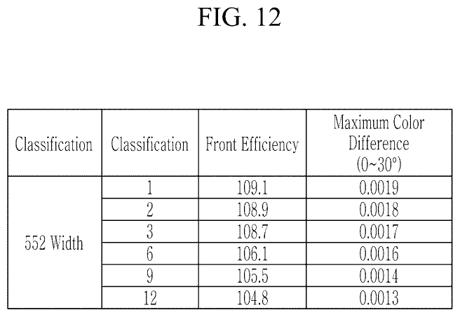

Therefore, it can be confirmed that the expansion 552 provides a capillary phenomenon so that the second insulating layer 560 is uniformly disposed within the opening 551, but the efficiency of providing light toward the front (hereinafter referred to as front efficiency) deteriorates. Accordingly, a relationship between the lengths/widths of respective portions of the opening 551 will be described in more detail with reference to FIG. 12 to FIG. 17 below.

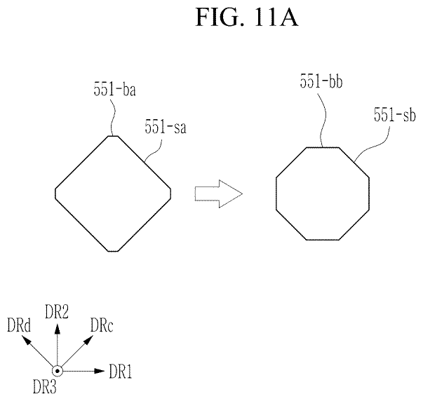

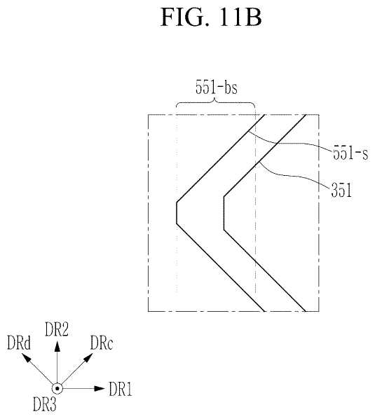

FIG. 11 shows changes occurring in the main portion including the chamfer portion 551-b and the side 551-s in case that the chamfer portion 551-b is largely formed.

FIG. 11 (A) shows the shape of the main portion of the opening 551 of the first insulating layer 550, excluding the expansion 552 thereof, and the changes in shape and the side 551-s by changing the chamfer portion 551-b from a short chamfer portion 551-ba to a relatively long chamfer portion 551-bb are shown. For example, according to FIG. 11 (A), it is shown that a regular octagon may be obtained by forming a long chamfer in a chamfered rhombic structure, and, it is shown that the side 551-s is also changed from a long side 551-sa to a relatively short side 551-sb.

FIG. 11 (B) shows a relationship between the chamfer portion 551-b and the pixel opening 351 according to the change of the chamfer portion 551-b.

In FIG. 11 (B), the chamfers 551-b that may be variously changed are shown as 551-bs with dotted lines.

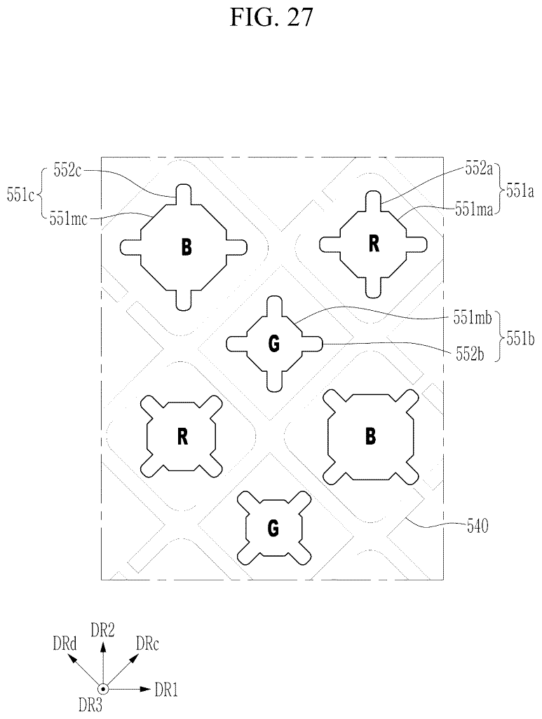

FIG. 11 (B) shows that as the length of the chamfer portion 551-b increases, the chamfer portion 551-b may overlap a boundary of the pixel opening 351 in a plan view or be disposed within the pixel opening 351. In case that the chamfer portion 551-b is disposed within the pixel opening 351, a portion of the light emitting layer disposed within the pixel opening 351 is covered with the first insulating layer 550 so that light is bent at the boundary between the first insulating layer 550 and the second insulating layer 560 to not propagate to the front, thus front efficiency may be reduced. Therefore, the length of the chamfer portion 551-b also needs to be changed to be long in consideration of the pixel opening 351, and the shape of the pixel opening 351 may be changed along with the change of the chamfer portion 551-b. Accordingly, the embodiment of FIG. 7 may have a regular octagonal main portion while the chamfer portion 551-b becomes long. In the following drawings, examples of the opening 551 of the first insulating layer 550 having the regular octagonal main portion, for example, in FIG. 27 to FIG. 31, may be applied to FIG. 7 as well.

Hereinafter, a width of the extension 552, a length of the chamfer portion 551-b, and a length ratio (Lᵣₐₜᵢₒ) of the opening part 551 of the first insulating layer 550 will be respectively described with reference to FIG. 12 to FIG. 14.

First, a numerical range of the width of the extension 552 according to the embodiment, and front efficiency and a color difference maximum value according to the numerical range will be described with reference to FIG. 12. Here, the color difference maximum value represents a value at which the color difference is a maximum in case that an azimuth angle is about 0 degrees or more and about 30 degrees or less.

Referring to FIG. 12, the width of the extension 552 may have a value in a range of about 1 μm to about 12 μm, and the front efficiency and the color difference value are shown for each width of the extension 552.

Referring to FIG. 12, it can be seen that the front efficiency decreases as the width of the extension 552 increases, but the color difference decreases as the width of the extension 552 increases. For example, since the front efficiency and the color difference are in a trade-off relationship with each other, the width of the extension 552 may be determined depending on which feature is used. An example in which the front efficiency is relatively high and the color difference is small may be in case that the width of the expansion 552 is about 3 μm.

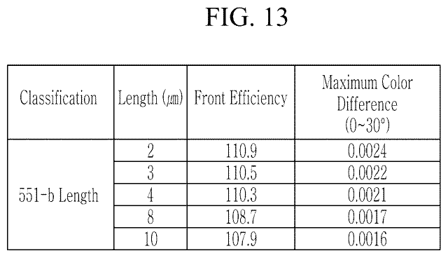

A numerical range of the length of the chamfer portion 551-b according to the embodiment, and front efficiency and a maximum value of a color difference according to the numerical range will be described with reference to FIG. 13.

Referring to FIG. 13, the length of the chamfer portion 551-b may have a value in a range of about 2 μm to about 10 μm, and the front efficiency and the color difference value are shown for each length of the chamfer portion 551-b.

Referring to FIG. 13, it can be seen that the front efficiency decreases as the length of the chamfer portion 551-b increases, but the color difference decreases as the length of the chamfer portion 551-b increases. For example, since the front efficiency and the color difference are in a trade-off relationship with each other, the length of the chamfer portion 551-b may be determined depending on which feature is used. An example in which the front efficiency is relatively high and the color difference is small may be in case that the length of the chamfer portion 551-b is about 8 μm. Here, in case that the length of the chamfer portion 551-b increases, this may be because the horizontal distance between the pixel opening 351 and the boundary between the first insulating layer 550 and the second insulating layer 560 decreases, and the amount of light provided from the light emitting layer that is not incident on the boundary increases.

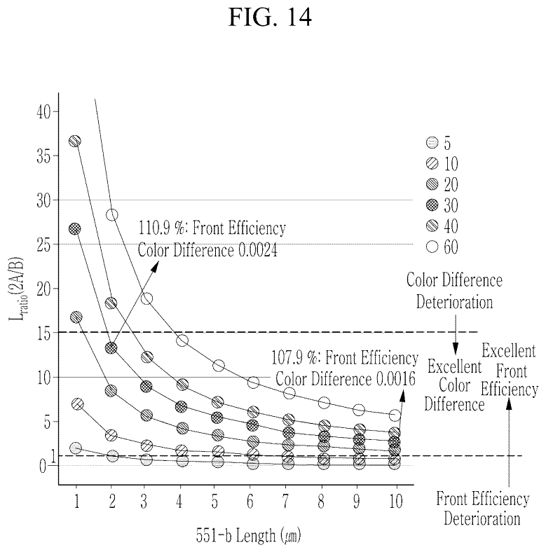

In FIG. 14, characteristics according to the length ratio (Lᵣₐₜᵢₒ) of the opening 551 of the first insulating layer 550 will be described.

Here, the length ratio (Lᵣₐₜᵢₒ) of the opening 551 of the first insulating layer 550 is as shown in Equation 2 below.

$${L}_{ratio} = \frac{2 A}{B} \qquad ( Equation 2 )$$

Here, A is A1 or A2 shown in FIG. 7, B is B1 or B2 shown in FIG. 7, 2A may be a value obtained by subtracting the width of the extension 552 from the length of one side or a side 551-s of the main portion, and B may be a length of the chamfer portion 551-b.

In FIG. 14, the length ratio (Lᵣₐₜᵢₒ) of the opening 551 of the first insulating layer 550 according to the change in the length of the chamfer portion 551-b is shown. For example, in case that the length of the chamfer portion 551-b increases, the length of the side 551-s relatively decreases accordingly, and the numerator value in Equation 2 decreases and the denominator value therein increases, so that the length ratio (Lᵣₐₜᵢₒ) of the opening 551 of the first insulating layer 550 is also reduced as a whole.

Referring to FIG. 14, it can be seen that front efficiency and the color difference are changed based on the length ratio (Lᵣₐₜᵢₒ) of the openings 551 of the first insulating layer 550. For example, in FIG. 14, it can be confirmed that in case that the length ratio of the opening 551 of the first insulating layer 550 is less than 1, since the front efficiency decreases, it needs to be 1 or more.

It can be confirmed that in case that the length ratio (Lᵣₐₜᵢₒ) of the opening 551 of the first insulating layer 550 exceeds 15, since the color difference depending on the angle is large such that the display quality may deteriorate, it needs to have a value of 15 or less.

Accordingly, the opening 551 of the first insulating layer 550 may be used by setting various length ratios (Lᵣₐₜᵢₒ) of 1 or more and 15 or less. The length ratio (Lᵣₐₜᵢₒ) of the opening 551 of the first insulating layer 550 is only the ratio of the length, so the shape or disposition thereof may be variously changed.

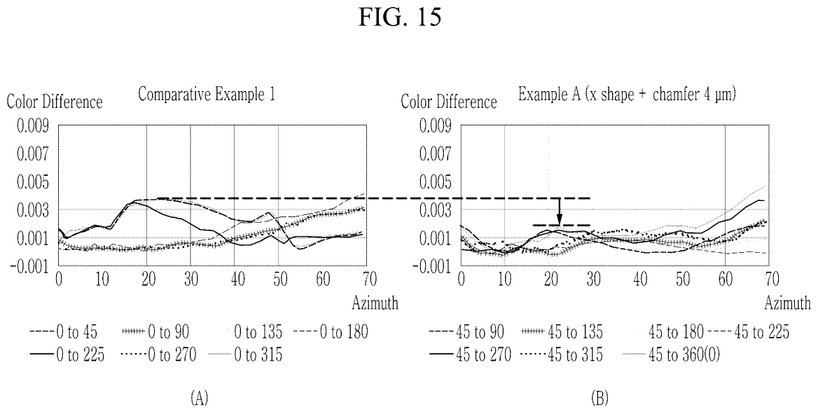

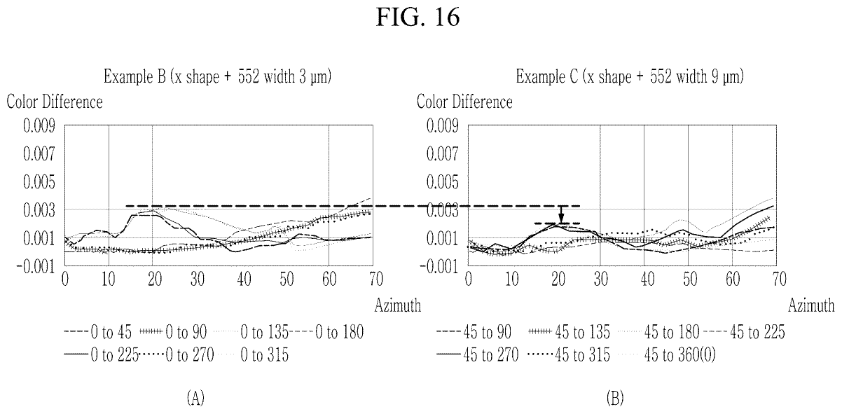

Hereinafter, a color difference according to an azimuth angle in Comparative Example 1 and Examples A, B, and C will be compared and described with reference to FIG. 15 and FIG. 16.

In graphs of FIG. 15 and FIG. 16, color difference values according to azimuth angles are shown wherein values of two viewing angles, which are standards for color difference, are different for each line of each graph, and the values of the two viewing angles are listed below the graph.

First, in FIG. 15, the color difference between Comparative Example 1 and Example A is compared and illustrated. Here, Comparative Example 1 is an example in which no chamfer portion is formed in the opening 551 of the first insulating layer 550 and no expansion 552 is formed. In contrast, Example A is an example in which the extension 552 protrudes in an x-shape as shown in FIG. 7, and the length of the chamfer portion 551-b is about 4 μm.

In FIG. 15, color difference values having a maximum value at an azimuth angle of about 30 degrees or less are compared with each other with a dotted line, and it can be seen that the color difference in Example A is clearly reduced compared to Comparative Example 1.

FIG. 16 shows a comparison of the color difference between Example B and Example C. Here, Example B is an example in which the expansion 552 protrudes in an x-shape as shown in FIG. 7, the chamfer portion 551-b is formed, and the width of the expansion 552 is about 3 μm, while Example C, unlike Example B, is an example in which the width of the expansion 552 is about 9 μm.

In FIG. 16, color difference values having a maximum value at an azimuth angle of about 30 degrees or less are compared with each other with a dotted line, and it can be seen that the color difference in Example C is clearly reduced compared to Example B. Therefore, it can be seen that the color difference decreases as the width of the extension 552 increases.

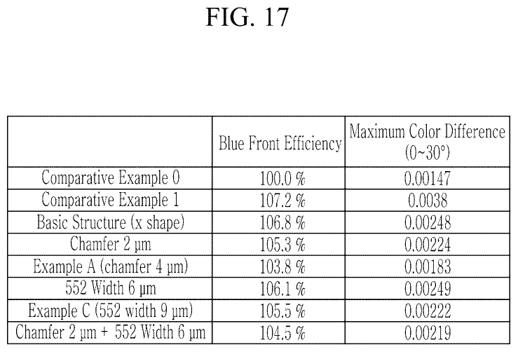

The above features will be compared and described with reference to FIG. 17 for the front efficiency and color difference by using various comparative examples and various examples.

In FIG. 17, Comparative Example 0 is an example in which the opening 551 of the first insulating layer 550 is not formed because the first insulating layer 550 and the second insulating layer 560 are not formed on the front surface of the light emitting layer. Comparative Example 1, as shown in FIG. 15, is an example in which no chamfer portion and no extension are formed in the opening 551 of the first insulating layer 550. A basic structure is an example in which no chamfer portion is formed in the opening 551 of the first insulating layer 550, but the extension 552 is formed in an x shape. “Chamfer 2 μm” in FIG. 17 is an example in which the chamfer portion 551-b is formed to be about 2 μm in the basic structure, while Example A (chamfer 4 μm) is an example in which, as shown in FIG. 15, the chamfer portion 551-b in the basic structure is formed to be about 4 μm. “552 width 6 μm” is an example that is similar to Example B of FIG. 16 but in which the width of the extension 552 is about 6 μm, unlike Example B, while “Example C (552 width 9 μm)” is an example in which the width of the extension 552 is about 9 μm, like Example C of FIG. 16. “Chamfer 2 μm+552 width 6 μm” is an example in which the chamfer portion 551-b is formed to be about 2 μm and the width of the extension 552 is about 6 μm in the basic structure.

In FIG. 17, the front efficiency of blue and the value of the maximum color difference at the azimuth angle of about 0 degrees or more and about 30 degrees or less are described.

Referring to FIG. 17, the front efficiency calculated by setting the front luminance of Comparative Example 0 to 100% is shown, and it can be confirmed that the front luminance is improved compared to Comparative Example 0 in all examples. The color difference is the smallest in Comparative Example 0, but compared to Comparative Example 1, it can be seen that the color difference is reduced in various examples. Therefore, in order to increase the front efficiency, the opening 551 of the first insulating layer 550 and the second insulating layer 560 may be formed, the extension 552 may be formed so that the second insulating layer 560 may uniformly fill the opening 551, and in order to reduce the color difference, the length of the chamfer portion 551-b and/or the width of the extension 552 may be adjusted. Referring to FIG. 14, the length ratio (Lᵣₐₜᵢₒ) of the opening 551 of the first insulating layer 550 in Equation 2 may have a value of 1 or more and 15 or less.

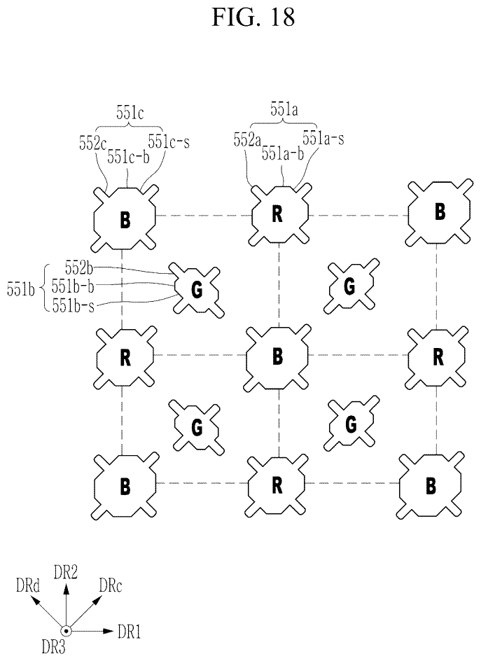

The opening 551 of the first insulating layer 550 having the structure described above may have various dispositions or may be modified, which will be described with reference to FIG. 18 to FIG. 25.

FIG. 18 to FIG. 25 show various modified examples of the opening 551 formed in the first insulating layer 550. In FIG. 18 to FIG. 25, a portion in which the opening 551 is not formed may be a portion covered with the first insulating layer 550.

In FIG. 18, an embodiment in which the opening 551 of the first insulating layer 550 having the x-shaped extension 552 as in FIG. 7 is formed to correspond to each of red (R), green (G), and blue (B) light emitting areas is shown. Here, the red (R), green (G), and blue (B) light emitting areas may correspond to the color of light displayed by the pixel opening 351 or the color of light emitted by a light emitting layer disposed within the pixel opening 351.

In FIG. 18, an opening 551a for red of the first insulating layer 550 corresponding to the light emitting area for red (R) may include a red side 551a-s, a red chamfer portion 551a-b, and a red extensions 552a. An opening 551b for green of the first insulating layer 550 corresponding to the light emitting area green (G) may include a green side 551b-s, a green chamfer portion 551b-b, and a green extension 552b. An opening 551c for blue of the first insulating layer 550 corresponding to the light emitting area for blue (B) may include a blue side 551c-s, a blue chamfer portion 551c-b, and a blue extension 552c. In an embodiment, the red, green, and blue may be changed to different colors, which may also be referred to as a first color, a second color, and a third color, respectively.

In the embodiment of FIG. 18, the openings 551c for blue and the openings 551a for red are alternately disposed in a first row, and the openings 551b for green are disposed in a second row. The openings 551a for red and the openings 551c for blue are alternately disposed in a third row, and the openings 551b for green are disposed in a fourth row.

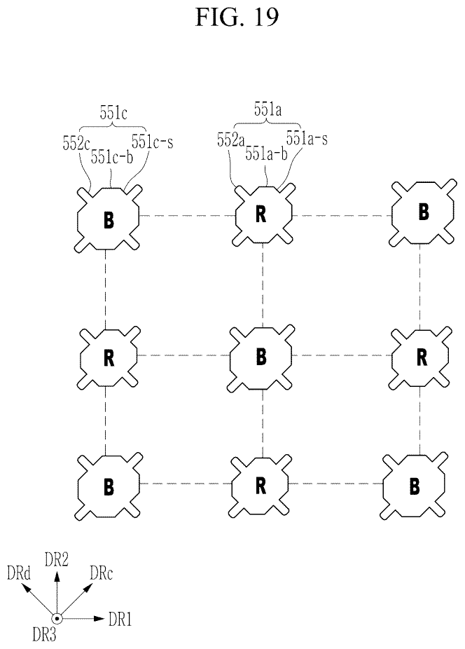

FIG. 19 to FIG. 21 are modified embodiments of the embodiment of FIG. 18, in which at least one of the opening 551a for red, the opening 551b for green, and the opening 551c for blue included in FIG. 18 is omitted. Here, the omission of one of the openings may mean that the corresponding light emitting area is covered with the first insulating layer 550 since the opening is not formed in the first insulating layer 550.

The embodiment of FIG. 19 is an embodiment in which the opening 551b for green is omitted from the embodiment of FIG. 18. In the embodiment of FIG. 19, the front efficiency of green may not be increased because green light is not bent in front.

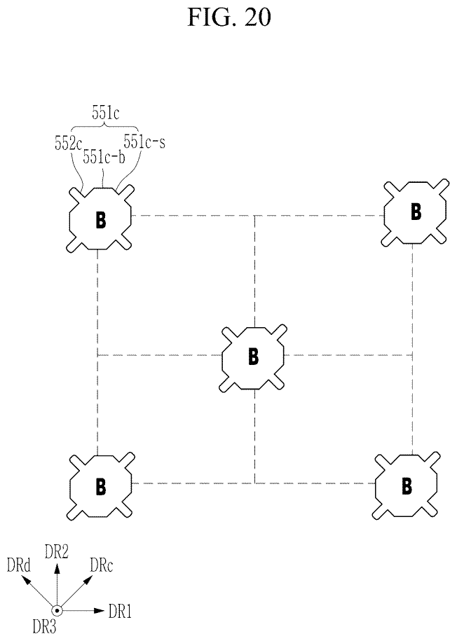

The embodiment of FIG. 20 is an embodiment in which the opening 551a for red and the opening 551b for green are omitted from the embodiment of FIG. 18. In the embodiment of FIG. 20, the front efficiency of red and green may not be increased because red and green light are not bent in front.

The embodiment of FIG. 21 is an embodiment in which the opening 551a for red and the opening 551c for blue are omitted from the embodiment of FIG. 18. In the embodiment of FIG. 21, the front efficiency of red and blue may not be increased because red and blue light are not bent in front.

Modified embodiments other than the embodiments of FIG. 19 to FIG. 21 may also be formed. In the embodiments of FIG. 19 to FIG. 21, only an embodiment in which openings of one color are omitted as a whole is shown, but an embodiment in which only some or a number of openings are omitted may also be formed.

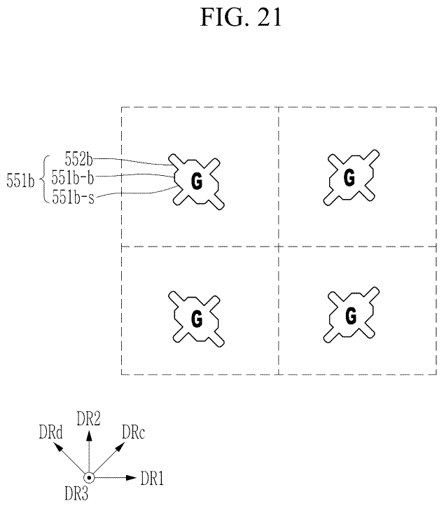

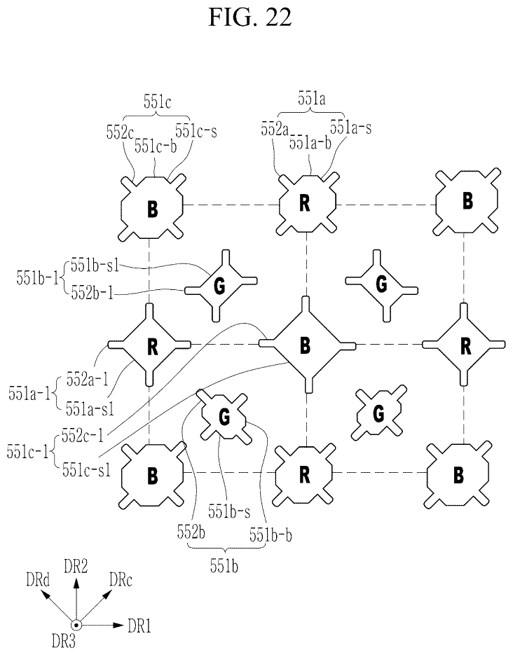

FIG. 22 to FIG. 25 show a modified embodiment of the opening 551 formed in the first insulating layer 550, and unlike FIG. 18 to FIG. 21, may include an opening (hereinafter also referred to as an additional opening) formed in the +-shaped direction that is different from the x-shaped direction as the direction of the extension 552.

In FIG. 22, unlike the embodiment of FIG. 18, additional openings 551a-1, 551b-1, and 551c-1 are formed. The additional openings 551a-1, 551b-1, and 551c-1 include extensions 552a-1, 552b-1, and 552c-1 disposed in a + shape.

In FIG. 22, the red additional opening 551a-1 of the first insulating layer 550 corresponding to the light emitting area for red (R) may include a red side 551a-s1 and a red extension 552a-1. The green additional opening 551b-1 of the first insulating layer 550 corresponding to the light emitting area green (G) may include a green side 551b-s1 and a green extension 552b-1. The blue additional opening 551c-1 of the first insulating layer 550 corresponding to the light emitting area for blue (B) may include a blue side 551c-s1 and a blue extension 552c-1. In an embodiment, since the red, green, and blue may be changed to different colors, they may also be referred to as a first color, a second color, and a third color, respectively.

In the embodiment of FIG. 22, the openings 551c for blue and the openings 551a for red are alternately disposed in a first row, and the additional openings 551b-1 for green are disposed in a second row. The red additional openings 551a-1 and the blue additional openings 551c-1 are alternately disposed in a third row, and the openings 551b for green are disposed in a fourth row. Referring to FIG. 9 and FIG. 10, since the direction in which light is provided is changed according to the direction of the extension 552, as shown in FIG. 22, both the extension disposed in the x shape and the extension disposed in the + shape are disposed, so that a difference in display quality depending on a direction may be prevented.

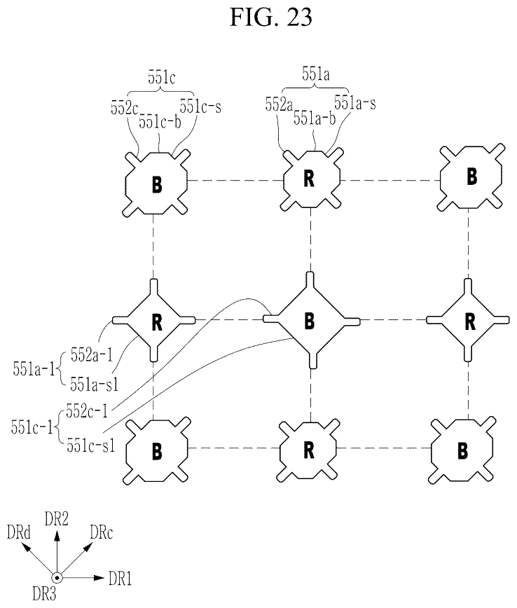

FIG. 23 to FIG. 25 are modified embodiments of the embodiment of FIG. 22, and are embodiments in which at least one of the opening 551a for red, the opening 551b for green, the opening 551c for blue, the red additional opening 551a-1, the green additional opening 551b-1, and the blue additional opening 551c-1 included in FIG. 22 is omitted. Here, the omission of one of the openings may mean that the corresponding light emitting area is covered with the first insulating layer 550 since the opening is not formed in the first insulating layer 550.

The embodiment of FIG. 23 is an embodiment in which the opening 551b for green and the green additional opening 551b-1 are omitted from the embodiment of FIG. 18. In the embodiment of FIG. 23, the front efficiency of green may not be increased because green light is not bent in front.

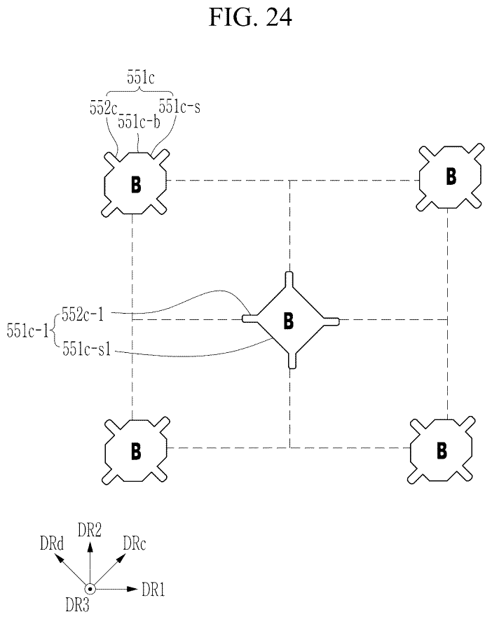

The embodiment of FIG. 24 is an embodiment in which the opening 551a for red, the opening 551b for green, the red additional opening 551a-1, and the green additional opening 551b-1 are omitted from the embodiment of FIG. 18. In the embodiment of FIG. 24, the front efficiency of red and green may not be increased because red and green light are not bent in front.

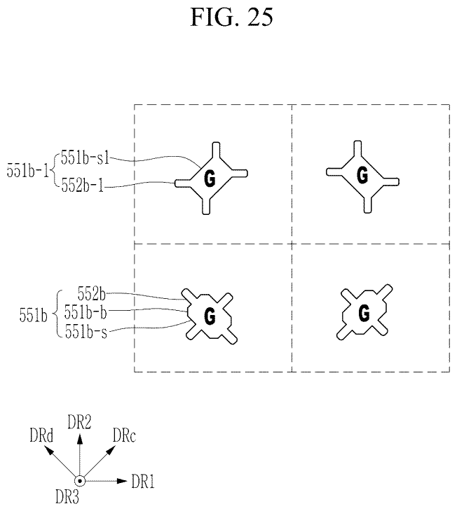

The embodiment of FIG. 25 is an embodiment in which the opening 551a for red, the opening 551c for blue, the red additional opening 551a-1, and the blue additional opening 551c-1 are omitted from the embodiment of FIG. 22. In the embodiment of FIG. 25, the front efficiency of red and blue may not be increased because red and blue light are not bent in front.

Modified embodiments other than the embodiments of FIG. 22 to FIG. 25 may also be formed. In the embodiments of FIG. 22 to FIG. 25, only an embodiment in which openings of one color are omitted as a whole is shown, but an embodiment in which only some openings are omitted may also be formed.

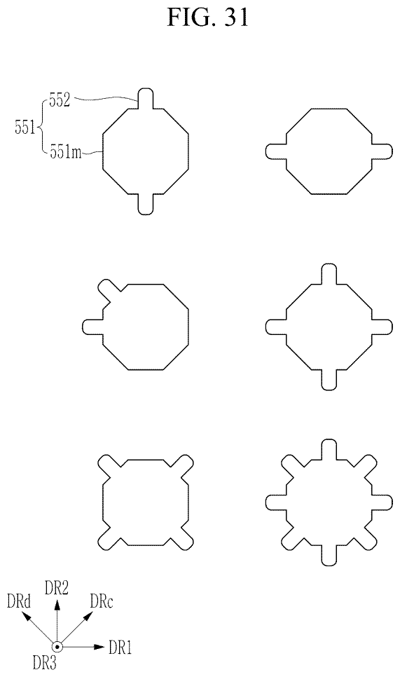

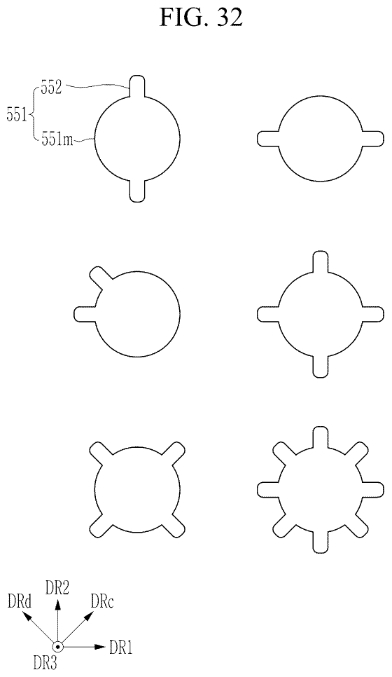

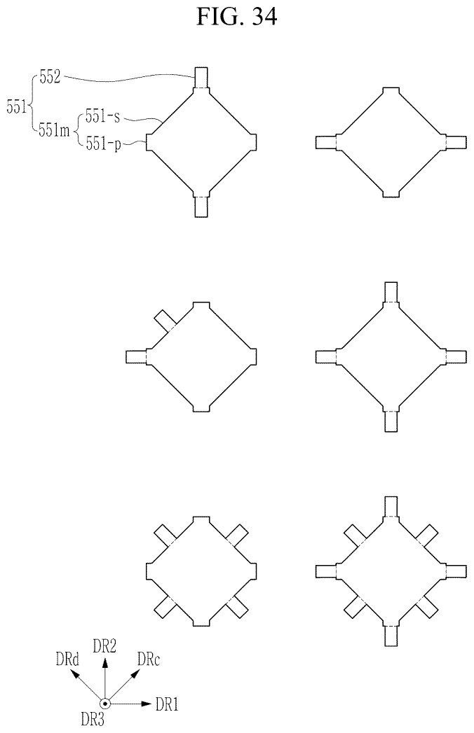

In an embodiment, the extension may be disposed in a shape other than a + shape or an x shape, and one of the examples may be the same as FIG. 31, FIG. 32, and FIG. 34 described later.

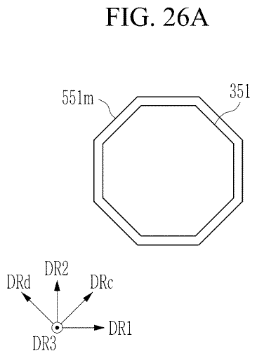

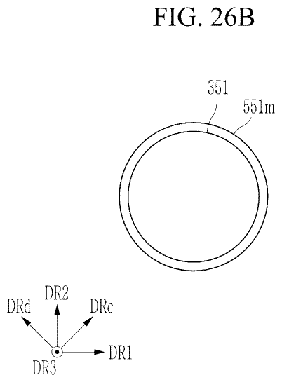

Hereinafter, the opening 551 of the first insulating layer 550 that does not include a chamfer portion and has an octagonal or higher polygonal or circular main portion will be described with reference to FIG. 26 and FIG. 32.

FIG. 26 illustrates a main portion of a first insulating layer according to an embodiment.

Referring to FIG. 26, in FIG. 26 (A), a regular octagonal main portion 551m is shown, and the pixel opening 351 disposed inside it in a plan view also has a regular octagonal planar shape. Unlike FIG. 26 (A), in an embodiment, the main portion 551m may be formed in a regular polygonal shape of a regular octagonal or higher shape. In FIG. 26 (B), a circular main portion 551m is shown, and the pixel opening 351 disposed inside B in a plan view also has a circular planar shape. Unlike FIG. 26 (B), in an embodiment, the main portion 551m may be formed in an elliptical shape. Therefore, unlike FIG. 26, the main portion 551m may be formed in an octagonal or higher polygonal shape, for example, in a nonagonal or decagonal planar shape, or in a circular or elliptical shape.

Since the opening 551 of the first insulating layer 550 further may include the extension in addition to the main portion, the extension may be disposed at a center or corner of one side or a side thereof.

In the embodiment of FIG. 26, the main portion 551m does not have a chamfered structure, and referring to FIG. 11 (A), in case that the length of the chamfer portion becomes longer, it may correspond to an octagonal shape, so that some or a number of sides of the octagonal shape may correspond to chamfered corners. However, in an embodiment, the corners may additionally include chamfers.

The opening 551 of the first insulating layer 550 having the main portion 551m as shown in FIG. 26 may have the same shape and disposition as shown in FIG. 27 to FIG. 32.

FIG. 27 to FIG. 32 illustrate openings of a first insulating layer according to various embodiments.

FIG. 27 to FIG. 30 also show a planar shape of the sensing electrode 540, and the sensing electrode 540 may be covered with the first insulating layer 550 as shown in FIG. 8.

First, the embodiment of FIG. 27 may include both an opening including an extension in the x-shaped direction and an opening including an extension in the +-shaped direction, as shown in FIG. 22.

For example, in the embodiment of FIG. 27, the opening 551a for red of the first insulating layer 550 corresponding to the light emitting area for red (R) may include a red main portion 551ma and a red extension 552a. The opening 551b for green of the first insulating layer 550 corresponding to the light emitting area of green (G) may include a main portion 551mb for green and an expansion 552b for green. The opening 551c for blue of the first insulating layer 550 corresponding to the light emitting area of blue (B) may include a main portion 551mc for blue and an expansion 552b for blue. In an embodiment, since the red, green, and blue may be changed to different colors, they may also be referred to as a first color, a second color, and a third color, respectively. In the opening 551a for red, the opening 551b for green, and the opening 551c for blue according to the embodiment of FIG. 27, the expansions 552a, 552b, and 552c are disposed in a + shape or an x shape, respectively.

In the embodiment of FIG. 27, the openings 551c for blue and the openings 551a for red are alternately disposed in the first row, and the expansions 552a and 552c of the opening 551c for blue and the opening 551a for red are disposed in a + shape, respectively. The opening 551b for green is disposed in the second row, and the extension 552b of the opening 551b for green is disposed in the + shape. The openings 551a for red and the openings 551c for blue are alternately disposed in the third row, and the expansions 552a and 552c of the opening 551a for red and the opening 551c for blue are respectively disposed in the x shape. The opening 551b for green is disposed in the fourth row, and the extension 552b of the opening 551b for green is disposed in the x shape.

Referring to FIG. 9 and FIG. 10, since the direction in which light is provided is changed according to the direction of the extension 552, as shown in FIG. 27, both the extension disposed in the x shape and the extension disposed in the + shape are disposed, so that a difference in display quality depending on a direction may be prevented.

Unlike the embodiment of FIG. 27, it may include only extensions disposed in the x shape or only extensions disposed in the + shape. Openings of the first insulating layer 550 are not formed to correspond to all colors, and openings of some colors may be omitted. In an embodiment, openings may be omitted for some of the same color light emitting areas.

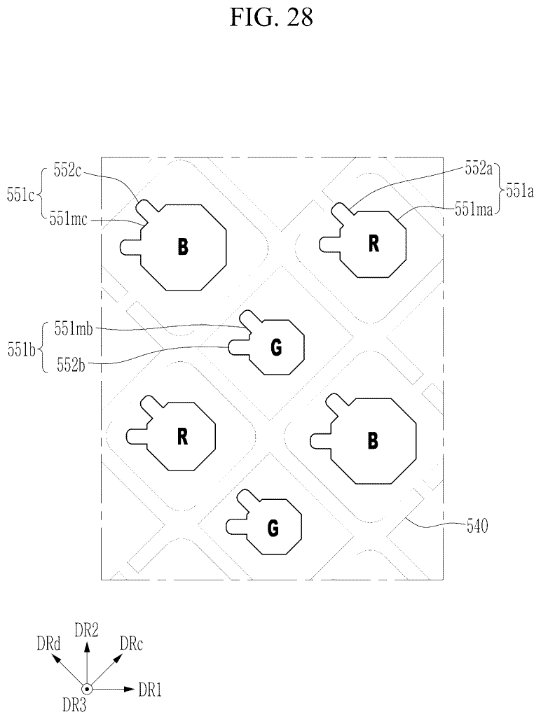

FIG. 28 to FIG. 32 are embodiments showing that the extension may be disposed in a shape other than the + or x shape.

In the embodiment of FIG. 28, only two expansions of 552a, 552b, and 552c are formed in the openings 551a, 551b, and 551c of the first insulating layer 550, and an angle between the two expansions of 552a, 552b, and 552c may be about 45 degrees.

In the embodiment of FIG. 28, directions of the two expansion portions of 552a, 552b, and 552c are disposed in the same direction. However, in an embodiment, in the openings 551a, 551b, and 551c of the at least one first insulating layer 550, the two extensions of 552a, 552b, and 552c may rotate to be disposed. Openings of the first insulating layer 550 are not formed to correspond to all colors, and openings of some colors may be omitted. In an embodiment, openings may be omitted for some of the same color light emitting areas.

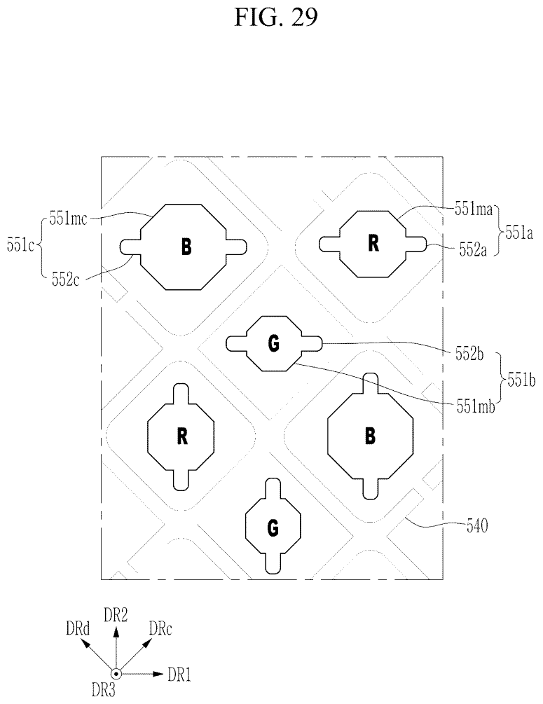

In an embodiment of FIG. 29, only two expansions of 552a, 552b, and 552c are formed in the openings 551a, 551b, and 551c of the first insulating layer 550 as shown in FIG. 28, but unlike FIG. 28, an angle between the two expansions of 552a, 552b, and 552c may be about 180 degrees.

In the embodiment of FIG. 29, the two extensions of 552a, 552b, and 552c include the openings 551a, 551b, and 551c of the first insulating layer 550 disposed along the second direction DR2 or disposed along the first direction DR1. However, in an embodiment, they may be disposed along one of the first direction DR1 and the second direction DR2. Openings of the first insulating layer 550 are not formed to correspond to all colors, and openings of some colors may be omitted. In an embodiment, openings may be omitted for some of the same color light emitting areas.

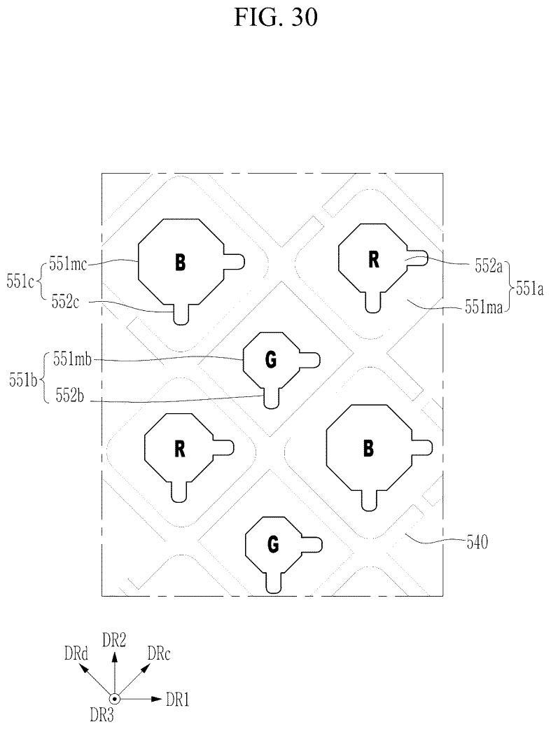

In the embodiment of FIG. 30, only two expansions of 552a, 552b, and 552c are formed in the openings 551a, 551b, and 551c of the first insulating layer 550 as shown in FIG. 28 and FIG. 29, but unlike FIG. 28 and FIG. 29, an angle between the two expansions of 552a, 552b, and 552c may be 90 about degrees.

In the embodiment of FIG. 30, in the openings 551a, 551b, and 551c of the first insulating layer 550, one of the two extensions of 552a, 552b, and 552c is disposed along the second direction DR2 and the other thereof is disposed along the first direction DR1. In the embodiment of FIG. 30, directions of the two expansion portions of 552a, 552b, and 552c are disposed in the same direction. However, in an embodiment, in the openings 551a, 551b, and 551c of the at least one first insulating layer 550, the two extensions of 552a, 552b, and 552c may rotate to be disposed. Openings of the first insulating layer 550 are not formed to correspond to all colors, and openings of some colors may be omitted. In an embodiment, openings may be omitted for some of the same color light emitting areas.

In FIG. 31 and FIG. 32, more various examples are shown with respect to the number and disposition direction of the expansion parts 552, and FIG. 31 illustrates the main portion 551m having a regular octagonal planar shape, while FIG. 32 illustrates the main portion 551m having a circular planar shape. The shapes of the main portion 551m may have various polygonal, circular, or elliptical shapes besides these.

Referring to FIG. 31 and FIG. 32, two, four, or eight extensions 552 may be included. In case that two extensions 552 are included, they may be disposed along the first direction DR1 or the second direction DR2 to form an angle of about 180 degrees or an angle of about 45 degrees. In case that four expansions 552 are included, they may be disposed in a + shape or an x shape. In case that eight extensions 552 are included, they may be disposed in a combination of a + shape and an x shape. Since the examples illustrated in FIG. 31 and FIG. 32 are only examples, various other modified examples are possible. An angle formed by two of extensions 552 may be about 45 degrees, about 90 degrees, or about 180 degrees, and in the example including eight extensions 552, two extensions 552 may form about 135 degrees. In an embodiment, the number and disposition of extensions 552 may vary, and the opening 551 of the first insulating layer 550 having different numbers and dispositions of extensions 552 may be formed together in one display device.

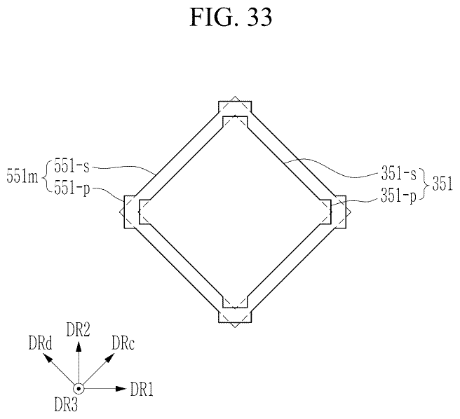

Hereinafter, a planar shape of the opening 551 of the first insulating layer 550 according to an embodiment will be described with reference to FIG. 33 and FIG. 34, and in the embodiment of FIG. 33 and FIG. 34, the opening 551 of the first insulating layer 550 has a protrusion 551-p formed at a corner portion of the main portion 551m.

FIG. 33 illustrates the main portion of the first insulating layer according to an embodiment.

Referring to FIG. 33, the main portion 551m that has a rhombic shape and may include the protrusion 551-p disposed near each corner thereof is shown. Here, the protrusion 551-p may correspond to the chamfer portion 551-b in the embodiment of FIG. 7. In an embodiment of FIG. 7, there is a problem that the chamfer portion 551-b may overlap the pixel opening 351 disposed therein in a plan view as the length of the chamfer portion 551-b increases (see FIG. 11), while in the embodiment of FIG. 33, since the protrusion 551-p is disposed, even if the length of the protrusion portion 551-p increases, the problem of overlapping the pixel opening 351 in a plan view may be eliminated.

The embodiment of FIG. 33 has a rhombic shape as a basic planar shape, but in an embodiment, it may have various polygonal shapes such as a circular shape, an elliptical shape, a quadrangular shape, and an octagonal shape. In an embodiment of FIG. 33, the protrusions 551-p are formed near all corners, but in an embodiment, the protrusion 551-p may be disposed only at least one of the corners.

The opening 551 of the first insulating layer 550 may further include an extension in addition to the main portion, and the extension protrudes from the main portion. The extension may be disposed at the center of one side or a side 551-s. The opening 551 of the first insulating layer 550 having the main portion 551m as shown in FIG. 33 may have one of the shapes shown in FIG. 34.

Referring to FIG. 33, the pixel opening 351 may have the same shape as the main portion 551m while maintaining a constant distance from it in a plan view. For example, like the main portion 551m, respective sides 351-s of the pixel opening 351 form a rhombic shape, and the pixel opening 351 may include protrusions 351-p disposed near respective corners of the rhombic shape.

FIG. 34 illustrates an opening of the first insulating layer according to an embodiment.

FIG. 34 illustrates various examples with respect to the number and disposition direction of the expansions 552. In FIG. 34, the main portion 551m has a shape having a protrusion 551-p based on a rhombic shape. The basic shape of the main portion 551m may have various polygonal, circular, or elliptical shapes in addition to the rhombic shape.

Referring to FIG. 34, the opening 551 of the first insulating layer according to the embodiment may include two extensions 552, four extensions 552, or eight extensions 552. In case that two extensions 552 are included, they may be disposed along the first direction DR1 or the second direction DR2 to form an angle of about 180 degrees or an angle of about 45 degrees. In case that four expansions 552 are included, they may be disposed in a + shape or an x shape. In case that eight extensions 552 are included, they may be disposed in a combination of a + shape and an x shape. Since the examples illustrated in FIG. 34 are only examples, various other modified examples are possible. An angle formed by two of extensions 552 may be about 45 degrees, about 90 degrees, or about 180 degrees, and in the example including eight extensions 552, two extensions 552 may form about 135 degrees. In an embodiment, the number and disposition of extensions 552 may vary, and the opening 551 of the first insulating layer 550 having different numbers and dispositions of extensions 552 may be formed together in one display device.

In the embodiment of FIG. 34, some or a number of the extensions 552 protrude from the protrusion 551-p, and the remaining ones thereof do not contact the protrusion 551-p and protrude from the side 551-s of the main portion 551m. By way of example, in an embodiment of FIG. 34, among the extensions 552, those having directions parallel to the first direction DR1 and the second direction DR2 protrude from the protrusion 551-p, but extensions not parallel to the first direction DR1 and the second direction DR2 protrude from the side 551-s.

In FIG. 34, a contact portion between the extension 552 and the protrusion 551-p is indicated by a dotted line. In the embodiment of FIG. 34, it can be seen that the width of the extension 552 is narrower than the width of the protrusion 551-p, so that a step occurs at the contact portion between the extension 552 and the protrusion 551-p. However, in an embodiment, the width of the extension 552 may be the same as the width of the protrusion 551-p, so that a step may not occur.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising
pixel electrodes disposed on a substrate;
a pixel defining film disposed on the pixel electrodes and including pixel openings respectively overlapping the pixel electrodes,
an encapsulation layer disposed on the pixel electrodes and the pixel defining film;
a sensing electrode disposed on the encapsulation layer;
a first insulating layer disposed on the sensing electrode and including openings respectively overlapping the pixel openings; and
a second insulating layer disposed on the first insulating layer and having a higher refractive index than a refractive index the first insulating layer, wherein
each of the openings of the first insulating layer includes a main portion including a side and a chamfer portion and an extension protruding from the main portion, and
in case that a value obtained by subtracting a width of the extension from a length of the side of the main portion is 2A, and a length of the chamfer portion is B, and
a value of 2A/B is in a range of about 1 to about 15.

2. The display device of claim 1, wherein the width of the extension is in a range of about 1 μm to about 12 μm.

3. The display device of claim 1, wherein the length of the chamfer portion is in a range of about 2 μm to about 10 μm.

4. The display device of claim 1, wherein a planar shape of the main portion including the chamfer portion is a substantially octagonal shape, and includes four extensions.

5. The display device of claim 4, wherein the extensions are disposed in a substantially x shape.

6. The display device of claim 5, wherein the extension is disposed at a center of the side of the main portion of the first insulating layer.

7. The display device of claim 4, wherein
the first insulating layer includes additional openings, and
each of the additional openings includes extensions disposed in a substantially + shape.

8. The display device of claim 4, wherein a planar shape of the main portion including the chamfer portion is a substantially regular octagonal shape.

9. The display device of claim 1, wherein each of the openings of the first insulating layer includes two extensions, four extensions, or eight extensions.

10. The display device of claim 9, wherein two of the extensions form an angle of about 45 degrees, about 90 degrees, about 135 degrees, or about 180 degrees.

11. A display device comprising:
pixel electrodes disposed on a substrate;
a pixel defining film disposed on the pixel electrodes and including pixel openings respectively overlapping the pixel electrodes;
an encapsulation layer disposed on the pixel electrodes and the pixel defining film;
a sensing electrode disposed on the encapsulation layer;
a first insulating layer disposed on the sensing electrode and including openings respectively overlapping the pixel openings; and
a second insulating layer disposed on the first insulating layer and having a higher refractive index than a refractive index of the first insulating layer, wherein
each of the openings of the first insulating layer includes a main portion and extensions protruding from the main portion, and
the main portion includes a protrusion at each corner of the main portion.

12. The display device of claim 11, wherein each of the openings of the first insulating layer includes two extensions, four extensions, or eight extensions.

13. The display device of claim 12, wherein two of the extensions form an angle of about 45 degrees, about 90 degrees, about 135 degrees, or about 180 degrees.

14. The display device of claim 11, wherein a width of the protrusion of the main portion is greater than a width of an extension of the extensions.

15. The display device of claim 14, wherein at least one of the extensions protrudes from the protrusion of the main portion.

16. The display device of claim 15, wherein a step is formed at a portion in which an extension protruding from the protrusion and the protrusion contact each other.

17. The display device of claim 14, wherein at least one of the extensions does not contact the protrusion.

18. A display device comprising:
pixel electrodes disposed on a substrate;
a pixel defining film disposed on the pixel electrodes and including pixel openings respectively overlapping the pixel electrodes;
an encapsulation layer disposed on the pixel electrodes and the pixel defining film;
a sensing electrode disposed on the encapsulation layer;
a first insulating layer disposed on the sensing electrode and including openings respectively overlapping the pixel openings; and
a second insulating layer disposed on the first insulating layer and having a higher refractive index than a refractive index of the first insulating layer, wherein
each of the openings of the first insulating layer includes a main portion and an extension protruding from the main portion, and
a planar shape of the main portion has a substantially regular polygonal shape equal to or greater than a substantially regular octagonal shape.

19. The display device of claim 18, wherein each of the openings of the first insulating layer includes two extensions, four extensions, or eight extensions.

20. The display device of claim 19, wherein two of the extensions form an angle of about 45 degrees, about 90 degrees, about 135 degrees, or about 180 degrees.
